(19) United States
(12) Patent Application Publication
(10) Pub. No.: US 2023/0368652 A1
(43) Pub. Date: Nov. 16, 2023

(54) CONTROL DEVICE FOR ENABLING RF CONTROL IN A USER ENVIRONMENT

(71) Applicant: The Magic of Things Ltd., London (GB)

(72) Inventors: Matthew Cortland, London (GB); Lyudmil Yordanov Atanasov, London (GB); Tanat Kriengkomol, London (GB)

(73) Assignee: The Magic of Things Ltd., London (GB)

(21) Appl. No.: 18/196,781

(22) Filed: May 12, 2023

Related U.S. Application Data
(60) Provisional application No. 63/341,315, filed on May 12, 2022.

(51) Int. Cl. G08C 17/02; H03K 17/96; H03K 17/95

(52) U.S. Cl. CPC G08C 17/02; H03K 17/962; H03K 17/95; H03K 2217/9607

(57) ABSTRACT

A master control device in the configuration of a wand may control pre-programmed aspects of the user's environment using RFID/NFC tags and RFID/NFC readers to initiate pre-programmed behavior in a computer database. This pre-programmed behavior may be the control of items that rely on electricity and/or gas, such as lights, electric fireplaces, electric valves, activating the listening feature on a home assistant, accruing a balance, paying for items with a topped-up balance, and locking and unlocking doors. This master control device can be used in the connected home or business, such as a pub, restaurant, hotel, or immersive experience. A smart home device and/or smart socket may be used with the master control device in order to perform control of a controllable device.

### CROSS-REFERENCE TO RELATED APPLICATIONS

This application claims the benefit of U.S. Provisional Application No. 63/341,315, filed May 12, 2022, the entire contents of which are incorporated by reference herein.

### BACKGROUND

In recent years there has been a wave of innovation in Internet of Things (IoT) technology for consumer use. The growing popularity of home assistants, such as Alexa and Google Home, as well as home automation systems like Nest, mean that this technology is reaching a mainstream audience. Now more than ever, a person can control aspects of the home using a smartphone, voice command, or gesture.

Radio frequency identification (RFID) and near-field communication (NFC) technology has been implemented in various products and systems. RFID and NFC uses range from tracking of goods and items to processing payments. RFID and NFC technology, however, can be utilized to improve various elements of IoT technology to control aspects of a user's environment.

A Hall effect sensor may be a device that is used to measure the magnitude of a magnetic field. Hall effect sensors may be used for proximity sensing, positioning, speed detection, and/or current sensing applications, and may be combined with threshold detection (e.g., such that they act as a switches). A Hall effect sensor may trigger a switch when it is in proximity to a magnet.

Capacitive touch technology may use a conductive touch (e.g., of a human finger and/or a specialized device) for input. Capacitive touch technology may be used in, for example, smartphone and/or Internet of things (IoT) technology screens to allow a user to control the device with one or more fingers. When a capacitive panel or circuit is touched, a relatively small amount of charge may be drawn to the point of contact, which may become a functional capacitor.

### SUMMARY

Systems, methods, and apparatus are described herein for controlling a user's environment using short-range communication signals and the Internet of Things (IoT). A universal receiver (UR) is disclosed herein that may control aspects of a user's environment based on short-range communication signals received from a master control device (e.g., a user control device). For example, the universal receiver may be a universal wand receiver (UWR) that communicates with the master control device as disclosed herein. The UWR may include a short-range communication circuit, such as a radio frequency (RF) circuit, a Hall effect sensor, and/or a near-field communication (NFC) circuit, configured to transmit and/or receive short-range communication signals, such as RF signals or NFC signals. The short-range communication signals may include a unique identifier, such as an RFID or other serial number. When a Hall effect sensor is used, the short-range communication signals may trigger a switch. The unique identifier may be associated with the master control device.

The short-range communication signals may be received by the UWR and used to detect the presence of a high frequency, passive transponder (e.g., an RFID tag). The transponder may be located within the master control device, for example as part of a control circuit. The control circuit may include an LED and/or a means to power the transponder and/or the LED. The transponder may be encased in a casing (e.g., made of glass, plastic, resin, and/or the like), which may limit the interference of a short-range communication signal, and embedded in the tip of the master control device. The UWR may transmit and/or receive data via a compatible microchip reader of the same frequency and protocol as the signals being transmitted from the master control device. For example, the master control device may transmit the signals via RFID, NFC, Bluetooth, WiFi, and/or the like.

The UWR may be a computing device that has stored thereon, or has access to, a database or other dataset of pre-programmed actions that may be performed in response to the short-range communication signals received from the master control device. Once the RFID/NFC reader of the UWR has successfully read the data from the master control device, the computer database to which the reader is attached may perform a pre-programmed action that performs some further action. For example, the reader may be attached to a door lock, and the computer database may send a signal to the lock to unlock.

In one example, the master control device may include an elongated magic wand. The elongated magic wand may be made of plastic, glass, metal, wood, silicon, hardened resin, PLA, PLA Composite, and/or the like. The elongated magic wand may include the RFID tag in glass tubing embedded in the tip of the master control device. The elongated magic wand may include memory for storing the unique identifier and/or other data. The elongated magic wand may include a processor configured to send the identifier and/or other data via the short-range communication signals sent via the transponder. The elongated magic wand may include one or more batteries, a PCB (e.g., a touch-capacitive PCB), one or more LEDs, and/or one or more types of resins or PLAs.

The master control device may be manufactured to contain the control circuit. The control circuit (e.g., within a tubing) may be placed into a mold. The mold may be filled with a liquid substance (e.g., plastic or resin) that may surround the control circuit. Alternatively, the master control device may be manufactured using 3D printing techniques. The 3D-printed master control device may have an empty space where the control circuit can be inserted after printing.

The master control device may be used to dispense a drink. For example, the master control device may be assigned to a given user. The reader may be attached to a drink dispenser (e.g., a beer tap). The user may place the wand near the reader in order to dispense the drink. The UWR may record the amount of liquid that has been dispensed and pass that information to a database, where a monetary value is assigned to that volume of liquid. Upon check-out, the user may be charged according to the amount of drink that is dispensed.

The master control device may be used to interact with a controllable device that is plugged into a smart socket. For example, the master control device may include a magnet. The magnet may be brought within range of a Hall effect sensor, which may be located within a universal transmitter (UT). The UT may transmit an indication to the smart socket via RF signals. The smart socket may receive the indication, and may change a state of the controllable device. For example, the smart socket may turn the controllable device on or off. Alternatively, the controllable device may be a smart home device, and the smart socket may cause the smart home device to enter an active/listening state.

### BRIEF DESCRIPTION OF THE DRAWINGS

FIG. 1 illustrates an example master control device with capacitive touch control.

FIG. 2A is a diagram that illustrates an example communication circuit that may be used as part of a master control device.

FIG. 2B is a diagram that illustrates an example of a printed circuit board (PCB).

FIG. 2C is a diagram that illustrates an example control circuit that may be used as part of a master control device.

FIG. 2D illustrates side-on and top-down views of a control circuit residing in the tip of a master control device.

FIG. 3 shows an example block diagram of a universal controller (UC) with which the master control device may be in communication.

FIG. 4 shows a block diagram of an example simple controller (SC).

FIG. 5A illustrates a diagram of a cross-sectional side view of an example silicon mold that may be used for manufacturing the master control device.

FIG. 5B illustrates a diagram of a cross-sectional front view of the silicon mold that may be used for manufacturing the master control device.

FIG. 6 illustrates a diagram of an example process for manufacturing a master control device using a three-dimensional 3D printing technique.

FIG. 7A illustrates a diagram of an example configuration for a distal end of the shaft of the master control device.

FIG. 7B illustrates a diagram of an example master control device formed in two pieces that are later attached.

FIG. 8A illustrates a diagram of an example control system in which the master control device may interact with a UR to complete a specific action.

FIG. 8B illustrates a diagram of an example control system in which the system of FIG. 8A may be integrated with a smart device.

FIG. 8C illustrates another diagram of an example control system in which the master control device may interact with a UR to complete a specific action.

FIG. 8D illustrates a diagram of an example control system in which the system of FIG. 8C may be integrated with a smart device.

FIG. 8E illustrates a diagram of an example control system in which the master control device may interact with a universal transmitter (UT) via a tip component.

FIG. 9A illustrates a diagram of an example system where the master control device may be used to dispense a drink with gas.

FIG. 9B illustrates a diagram of an example system where the master control device may be used to dispense a drink using gravity.

FIG. 10 is a diagram that illustrates an example of a PCB for touch capacitance.

FIG. 11 is a diagram that illustrates an example capacitive touch circuit that may be used as part of the master control device.

FIG. 12A is a diagram that illustrates components that may be assembled into an example master control device.

FIG. 12B is a diagram that illustrates an example master control device that incorporates the components shown in FIG. 12A.

FIG. 13A is another diagram that illustrates components that may be assembled into an example master control device.

FIG. 13B is a diagram that illustrates an example master control device that incorporates the components shown in FIG. 13A.

FIG. 14A is a diagram that illustrates components that may be assembled into an example master control device.

FIG. 14B is a diagram that illustrates an example master control device that incorporates the components shown in FIG. 14A.

FIG. 15 illustrates a diagram of example RFID and LED mounting geometries in the master control device.

FIG. 16 is a diagram that illustrates an example manufacturing of the master control device.

FIG. 17A is another diagram that illustrates components that may be assembled into an example master control device.

FIG. 17B is a diagram that illustrates an example master control device that incorporates the components shown in FIG. 17A.

### DETAILED DESCRIPTION

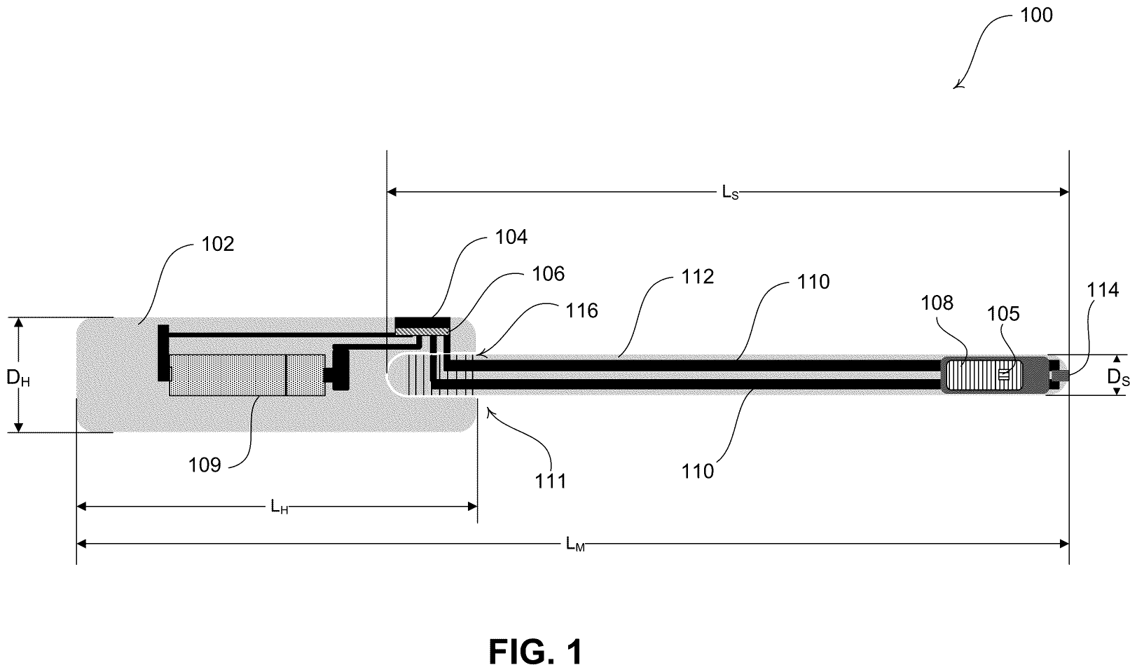

FIG. 1 illustrates an example master control device 100 with capacitive touch control. Master control device 100 may be in the shape of a wand, for example. The master control device 100 may have a handle 102 and a shaft 112. The master control device 100 may include a communication circuit 108. The communication circuit 108 may operate using radio frequency (RF) communications. For example, the communication circuit 108 may communicate a radio frequency identification (RFID), Bluetooth (e.g., Bluetooth low energy (BLE)), and/or Near Field Communication (NFC) signals for enabling control of devices in a user environment. The master control device 100 may interact (e.g., communicate) with a universal controller (UC) (not shown). For example, the communication circuit 108 may transmit a unique identifier associated with the communication circuit 108 to the UC (e.g., via an antenna) when the communication circuit 108 (e.g., the master control device 100) comes within a predefined RF range of the antenna.

The communication circuit 108 may include an LED 105. The LED 105 may turn on/off/blink to provide indications to the user. For example, the LED 105 may blink when the master control device 100 is turned on or off, the master control device 100 communicates with another device (e.g., a universal receiver), and/or another action is performed by the master control device 100.

The handle 102 may include an input area 104. The input area 104 may be a button that may be actuated by a user. The input area 104 may be a capacitive touch area that senses user input upon a user touch. The user may touch the input area 104 to interact with a control circuit 106 in the master control device 100. The control circuit 106 may be in direct communication with the input area (e.g., a capacitive touch control circuit) to receive input from the user. The control circuit 106 may send one or more signals via filaments and/or wires 110 to a resistor/LED 114. The resistor/LED 114 may be located at the distal end of the shaft 112. The resistor/LED 114 may be different from the LED 105. When the user touches the input area 104, the resistor/LED 114 may be illuminated. For example, the resistor/LED 114 may turn on, increase in lighting level over a period of time to a maximum lighting level, or blink. When the user touches the input area 104 again, or releases the touch from the input area, the resistor/LED 114 may be turned off, decrease in lighting level over a period of time to a minimum lighting level (e.g., off), or stop blinking. The filaments and/or wires 110 may be made of any suitable material. For example, filaments and/or wires 110 may be made of a graphite-PLA composite (e.g., if they are filaments), or copper (e.g., if they are wires).

The resistor/LED 114 and/or the control circuit 106 may be powered by a battery 109. For example, the battery 109 may be an AAA battery. The battery 109 may be replaceable via an opening 111 in the handle 102 where the handle 102 and shaft 112 are connected to each other.

The battery 109 may power other elements of the master control device 100 via the filaments and/or wires 110. The battery 109 may be a rechargeable battery and may be charged via induction (e.g., Qi charging). The battery 109 may be connected to a charging coil (not shown) that may be contained within the handle 102.

The handle 102 and the shaft 112 may be detachable from each other. For example, the handle 102 and the shaft 112 may be attached to each other by threads 116.

The master control device 100 may include a magnet (not shown). For example, the magnet may be located in the tip of the master control device. The magnet may be placed in addition to or alternatively to the communication circuit 108. For example, as described above, the master control device 100 may interact with a UC. The UC may include a sensor (e.g., a Hall effect sensor). The sensor may detect when the magnet enters within a pre-defined range of the sensor, and may indicate that the magnet is detected.

The master control device 100 may have a length L_{M} that is within the range of 250 mm to 350 mm. For example, the length L_{M} of the master control device 100 may be 270 mm to 330 mm. The length L_{M} of the master control device 100 may be 290 mm to 310 mm.

The handle 102 may have a length L_{H} within the range 120 mm to 200 mm. For example, the length L_{H} of the handle 102 may be 140 mm to 180 mm. The length L_{H} of the handle 102 may be may be 150 mm to 170 mm. The handle 102 may have a diameter DH within the range of 20 mm to 100 mm. The handle 102 may have a diameter DH within the range 40 mm to 80 mm. The handle 102 may have a diameter DH within the range of 50 mm to 70 mm.

The shaft 112 may have a length Ls within the range 150 mm to 200 mm. For example, the length Ls of the shaft 112 may be 160 mm to 190 mm. The length Ls of the shaft 112 may be 170 mm to 180 mm. The shaft 112 may have a diameter Ds within the range 8 mm to 15 mm. For example, the shaft 112 may have a diameter Ds of 9 mm to 14 mm. The diameter Ds of the shaft 112 may be 10 mm to 13 mm.

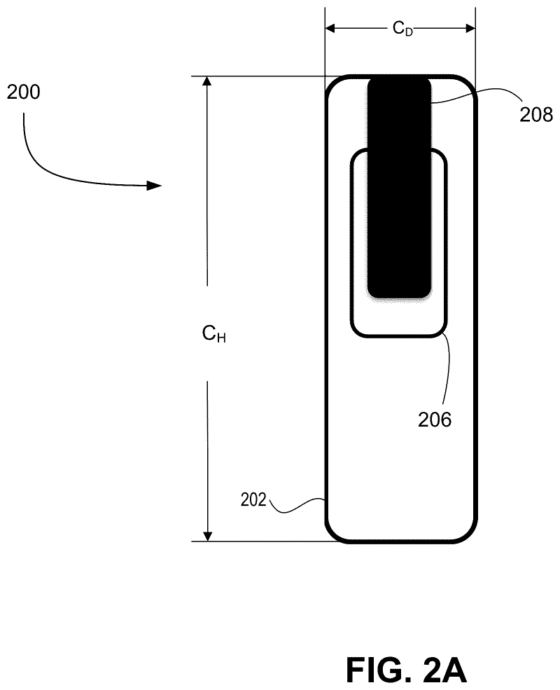

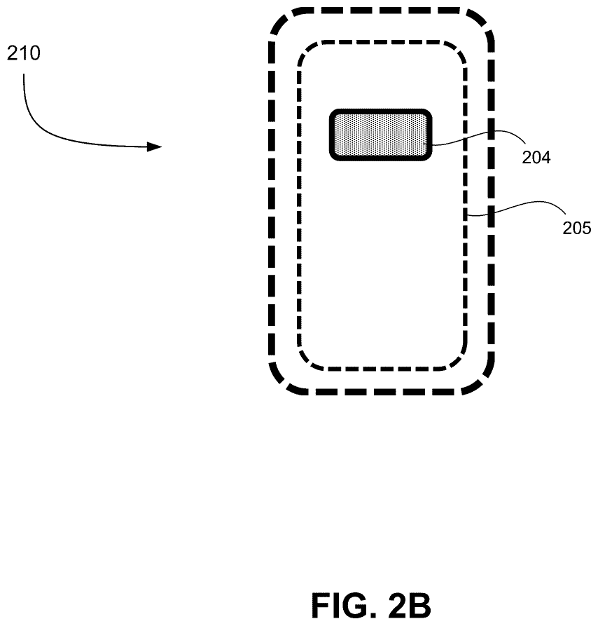

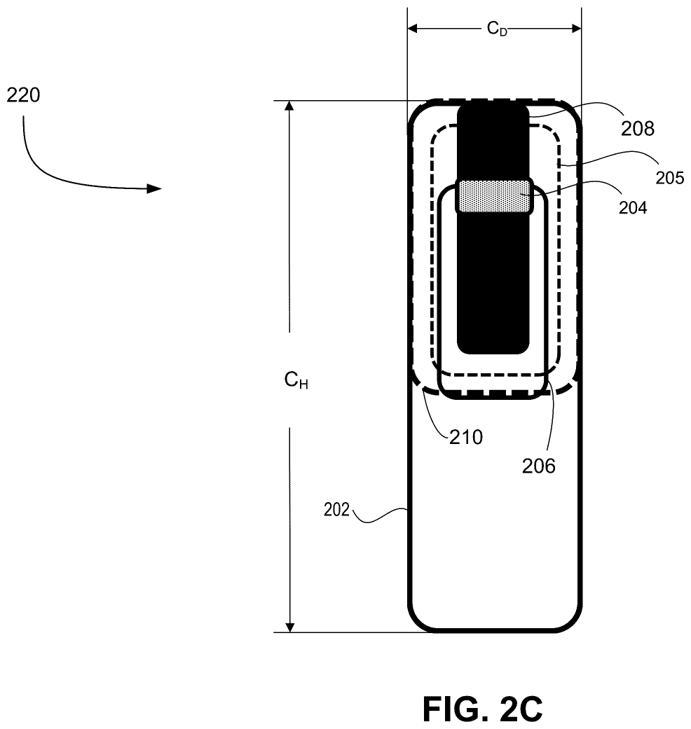

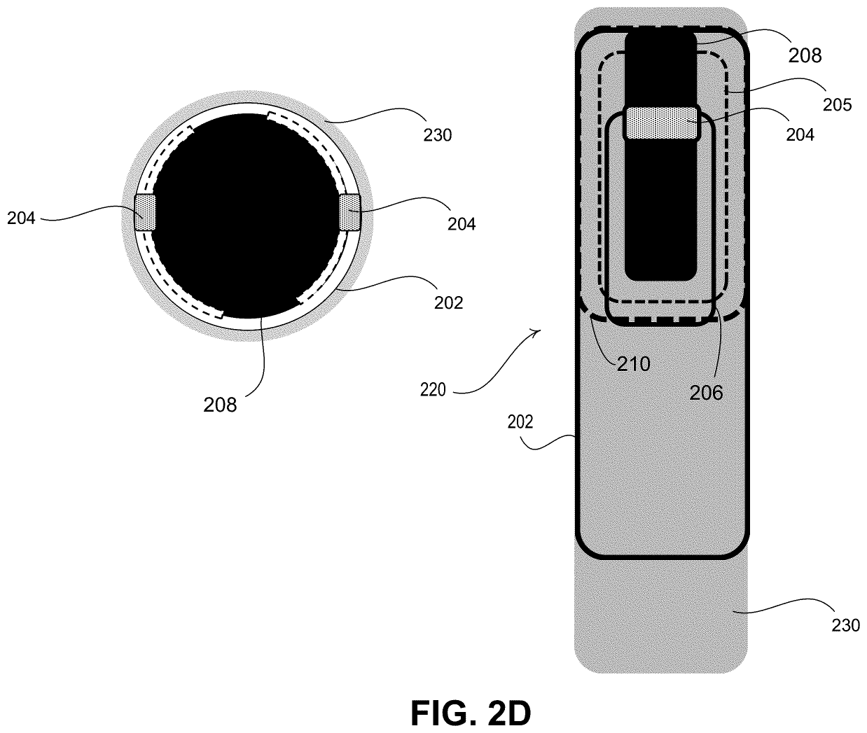

FIG. 2A is a diagram that illustrates an example communication circuit 200 that may be used as part of a master control device (e.g., the communication circuit 108 of the master control device 100 shown in FIG. 1) for controlling one or more devices in a user environment. The communication circuit 200 may operate using RF communications. For example, the communication circuit 200 may communicate via RFID, BLE signals, and/or NFC signals for enabling control of devices in a user environment.

The communication circuit 200 may include an embedded transponder 208. The transponder 208 may be a passive RFID tag. The passive RFID tag may enable the communication of the RFID when the RFID tag is within an RF range of an RFID reader and receives power from the RFID reader. Power may be supplied to the transponder 208 by a microchip reader (e.g., an RFID/NFC reader), which may be connected to a computer database. The communication circuit 200 may also, or alternatively, use an active RFID tag that may be battery powered to transmit an RFID by an internal battery power source (e.g., RFID beacon). Though a transponder 208 or RFID communications may be described, the transponder 108 may be an NFC transmitter or another transceiver or RF communication circuit capable of performing short-range wireless communications.

The communication circuit 200 may be housed in a tube (e.g., casing 202) and may contain one or more coiled antennas (e.g., coil 206) that form a magnetic field upon the receipt of RF signals, as shown in FIG. 2A. The coiled antenna 206 may provide power to the transponder 208 in the RFID tag via the RF signals. The casing 202 may enclose the communication circuit transponder 208 and/or the coiled antenna 206. The casing 202 may be configured such that it fits within an opening of the master control device.

The casing 202 may have a height C_{H} within the range 12 mm to 23 mm. For example, the height C_{H} of the casing 202 may be 14 mm to 21 mm. The height C_{H} of the casing 202 may be 16 mm to 19 mm. The casing 202 may have a diameter C_{D} within the range 2.12 mm to 3.85 mm. For example, the diameter C_{D} of the casing 202 may be 2.42 mm to 3.55 mm. The diameter C_{D} of the casing 202 may be 2.72 mm to 3.25 mm.

FIG. 2B is a diagram that illustrates an example of a printed circuit board (PCB) 210. The PCB 210 includes an RF controlled LED 204. There may be, for example, two RF controlled LEDs 204 (e.g., on opposite sides of the transponder 208). The RF controlled LED may be a passive NFC LED, but other RF controlled LEDs may also be implemented. The PCB 210 may include a coiled antenna (e.g., coil 205) that may be used to power the LED 204 when the coiled antenna comes within an RF range of an RF circuit, such as an NFC circuit or other RF circuit. The coil 205 may communicate via the same or different RF communications as the coil 206 illustrated in FIG. 2A.

Referring again to FIG. 2B, the LED 204 may provide feedback to the user. For example, the LED 204 may turn on or blink when, for example, the coil 205 is within an RF range of a universal receiver and/or performs communication with the universal receiver (e.g., after communication is sent, while communication is sending, and/or after receiving an acknowledgment message). The LED 204 may turn off or stop blinking when the coil 205 is outside of the RF range of the universal receiver and/or completes communication. The LED 204 may be a single color, or the LED 204 may use different colors to provide different forms of feedback.

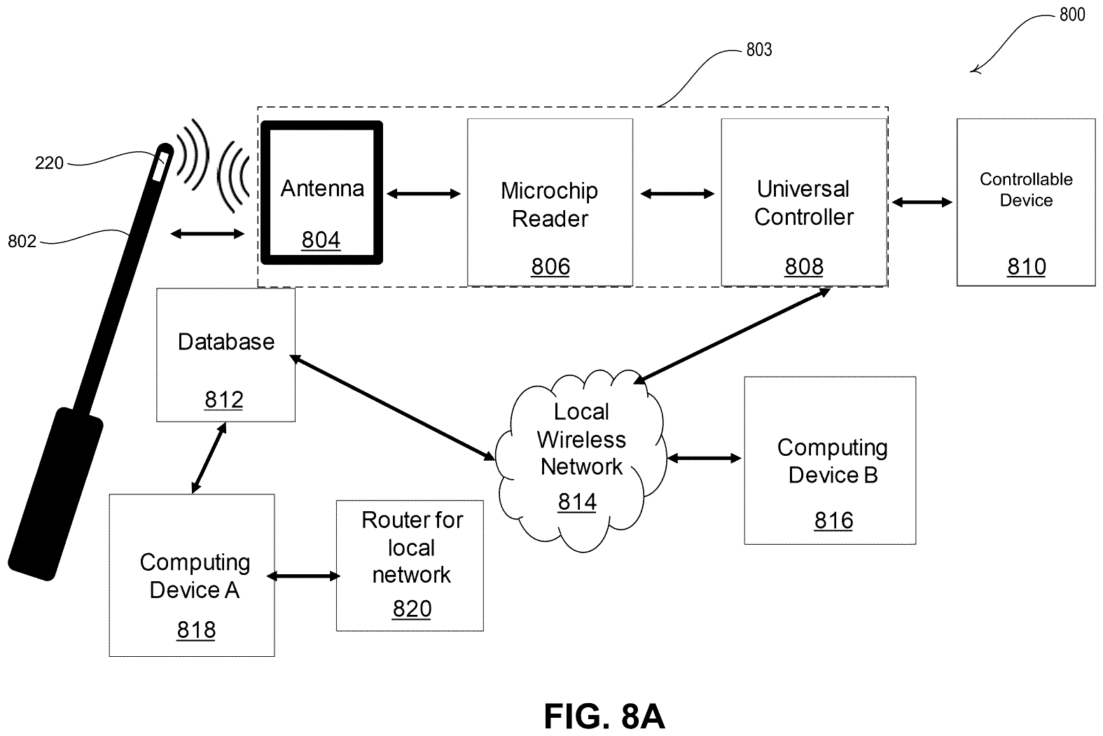

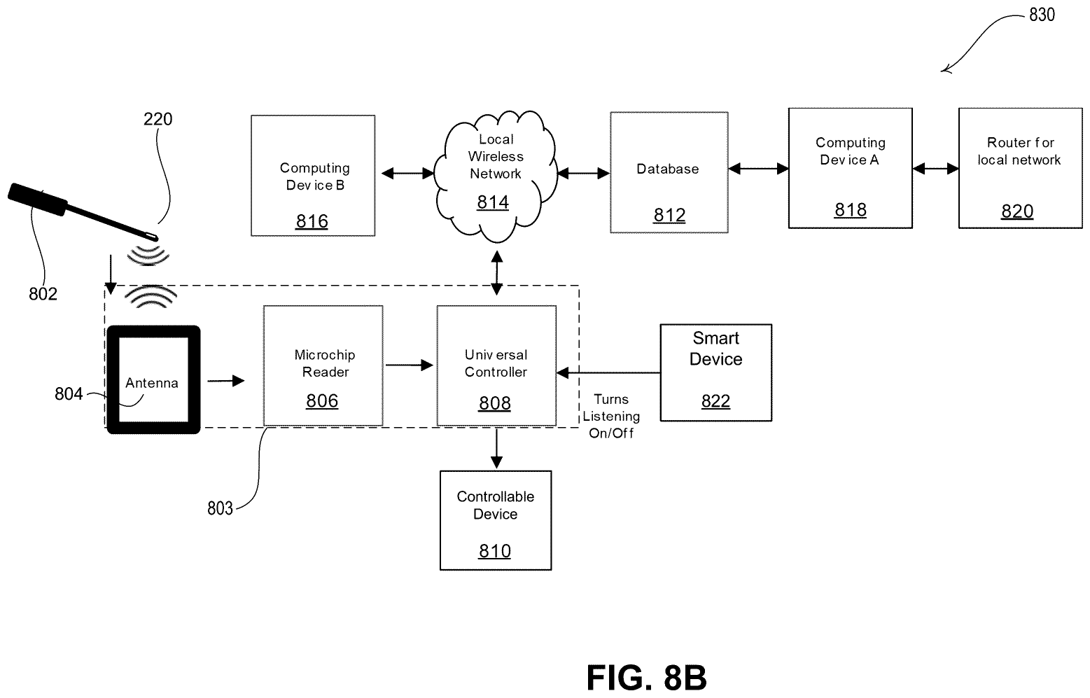

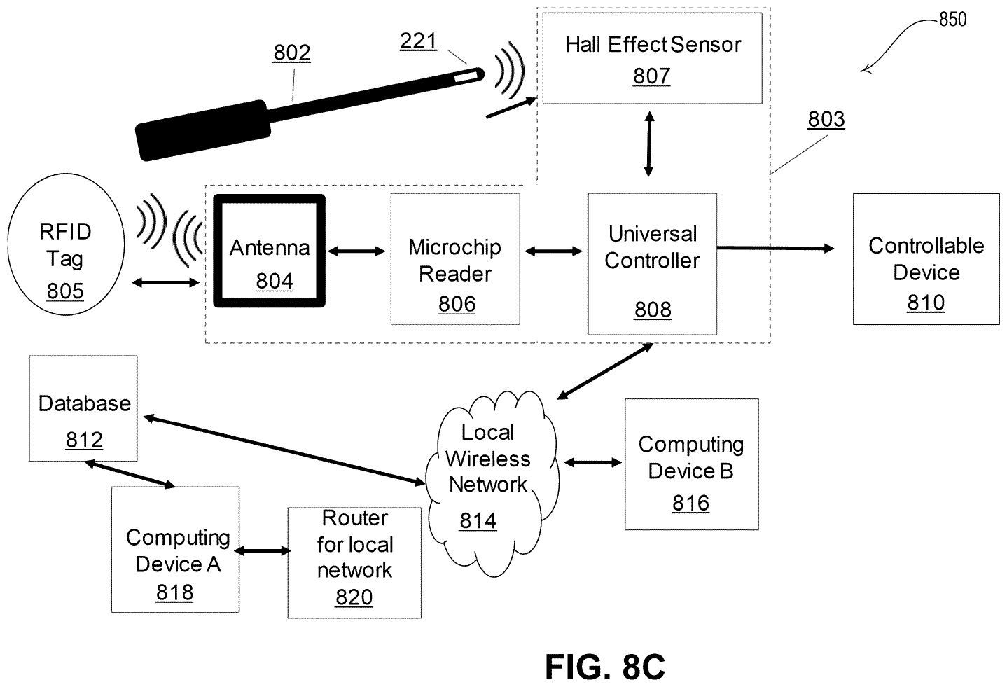

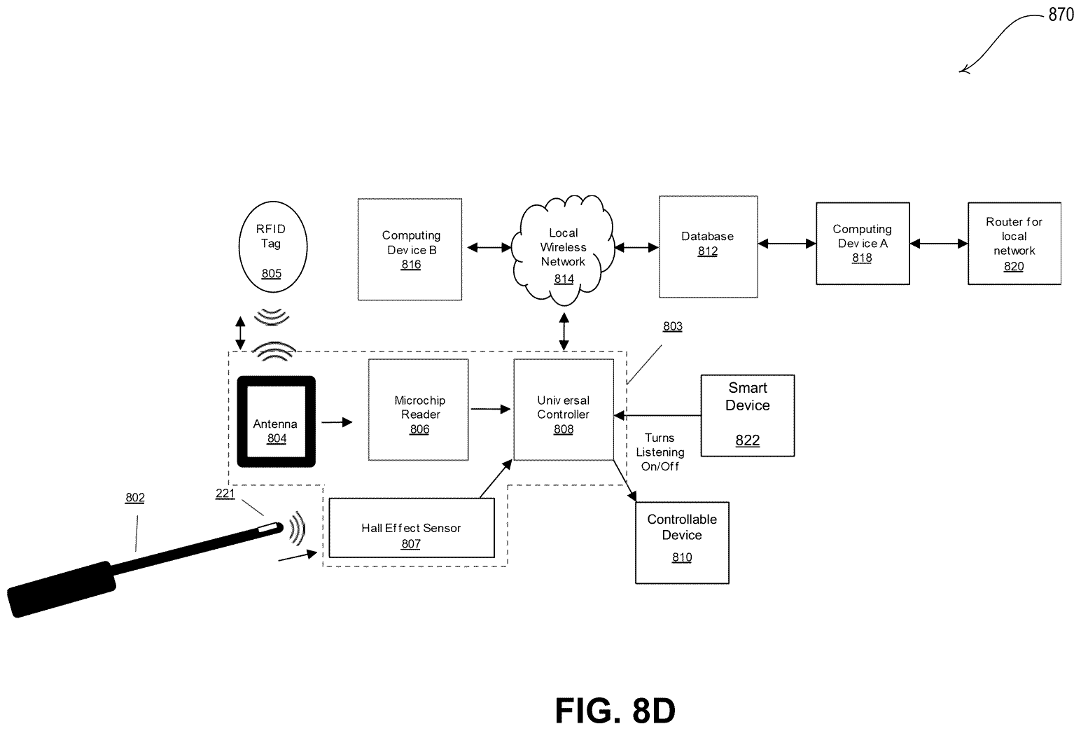

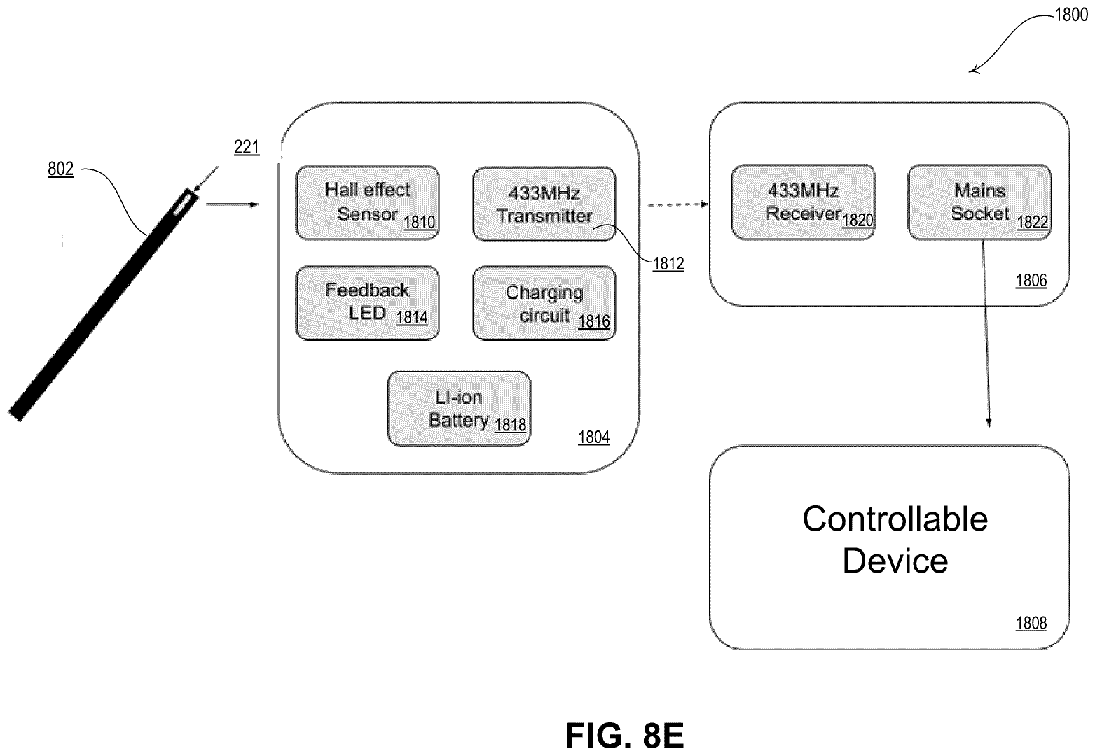

As shown in FIG. 2C, the PCB 210 may be included in the casing 202 with the transponder 208. The PCB may be a flexible PCB (FPCB) and may conform to an inner surface of the casing 202. The PCB 210 and/or the transponder 208 in the casing may be referred to as a control circuit 220 that may be used to perform control by communicating RF signals from a master control device. The casing 202 of the control circuit 220 may be transparent such that the LED 204 is visible through the casing 202 when active. The casing 202 may be made of any suitable material, including but not limited to glass, plastic, resin, metal, and/or the like. The coils 205, 206 may be made of any suitable material. The transponder 108 may have an associated unique identifier, and may transmit the unique identifier to a receiver (e.g., a Universal Wand Receiver (UWR)) upon the coil 206 being powered by the RF signals from the receiver. Though multiple coils 205, 206 are provided, the LED 204 may be in communication with the same coil that is used by the transponder 208. In an example, the control circuit 220 may include a magnet (e.g., the magnet 221 shown in FIG. 8A) that may be used to communicate with a Hall effect sensor.

FIG. 2D illustrates side-on and top-down views of the control circuit 220 residing in the tip of a master control device 230. The control circuit 220, encased in casing 202 and including coils 205, 206, LEDs 204, and/or transponder 208, may be inserted into a shaft 230 of a master control device. For example, the master control device may be in the shape of a wand, and shaft 230 may be located at the distal end of the wand. The shaft 230 may include a hollow portion, into which the control circuit 220 may be inserted. The control circuit 220 may be inserted into the hollow portion during manufacturing (e.g., the master control device may be manufactured around the control circuit 220), or after manufacturing. The shaft 230 may include a solid portion that may be located proximal to the hollow portion. The solid portion may act as a base for the control circuit 220 to sit upon. The portion of the shaft 230 surrounding the control circuit 220 may have a thickness within a range of 0.8 mm to 3 mm.

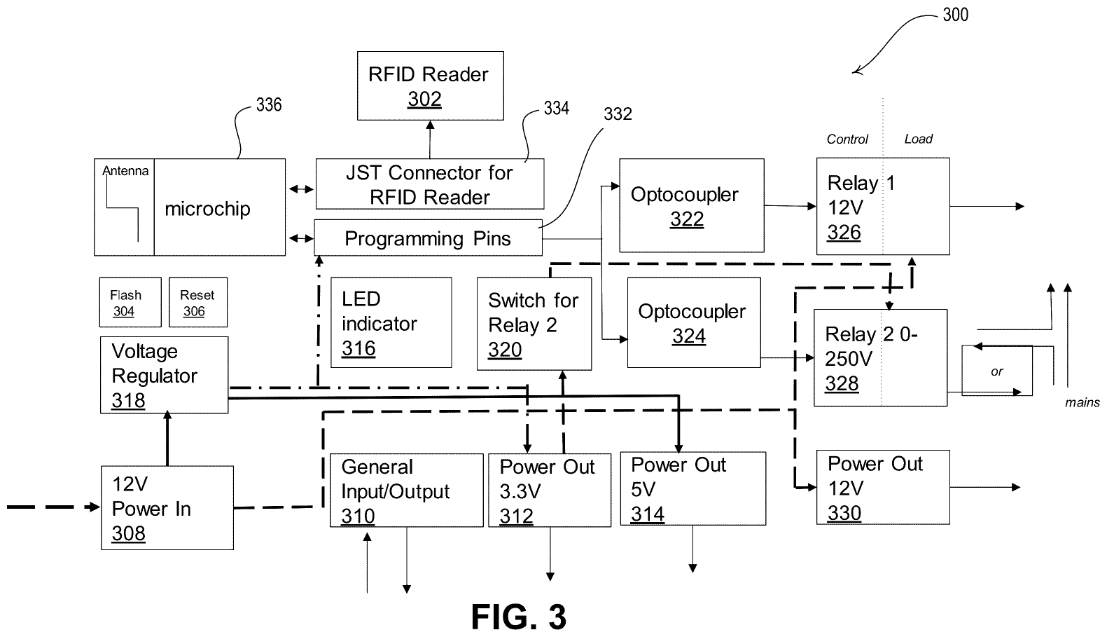

FIG. 3 shows an example block diagram of a universal controller (UC) 300 (e.g., a UWC) with which the master control device may be in communication. The UC 300 may be part of a universal receiver (UR). The UR may be, for example, a universal wand receiver (UWR).

The UC 300 may be and/or may include a printed circuit board (PCB). The UC 300 may include or be connected to a reader 302 for a given wireless communication protocol (e.g., RFID, NFC, and/or the like). The reader 302 may receive the unique identifier sent by the master control device (e.g., or another device), and may activate and/or deactivate one or more relays and/or pins.

Power may be provided to the UC 300 via a power input 308. The power input 308 may include 12V of power. For example, the power may be provided by a power source from an electric connection to a wall outlet or a 12V power bank. The power may be directed to a load via a first relay 326 (e.g., Relay 1), a switch 320 for a second relay 328 (e.g., Relay 2), a voltage regulator 318, and/or a 12V power out pin 330.

The first relay 326 may be used to power a load (e.g., on/off) in response to RF communications received from the master control device. The first relay 326 may use 12V. The first relay 326 may be rated for up to 250V. For example, the first relay 326 may provide a dedicated power source to a lock, a valve, or light source (e.g., LED) and provide power to lock/unlock the lock, turn on/off a valve, or turn on/off a light.

The switch 320 for the second relay 328 may allow for the load for the second relay 328 to be a switched electrical load to be powered on/off. The load powered via the second relay 328 may use between 0 and 250V, and the second relay 328 may be rated for up to 250V. The switch 320 for the second relay 328 may be used to turn on or off the electrical load receiving power from the second relay 328, such as a lamp powered from a different power source, in response to RF communications received from the master control device.

The power may pass through a voltage regulator 318. The voltage regulator 318 may drop the voltage (e.g., from 12V to, for example, 5V and/or 3.3V) for other types of electrical loads. The regulated voltage (e.g., 3.3V) may be provided to the microchip 336 and/or an RFID reader 302. The voltage also may be provided from the voltage regulator 318 to a power out 312 and/or a power out 314. The power out 314 may be a 5V power source and may be used to power one or more external devices (e.g., an LED, an LED strip, a neopixel LED ring, etc. comprising one or more colored LEDs) via the power out pin. The power out 312 may provide 3.3V of power. The power out 312 may be provided to a flow meter that measures the movement of a fluid provided through the flow meter from a source.

The general input-output 310 may be comprised of pins that may connect to a control source for adjusting input/output control for the amount of liquid provided through the flow meter. The control source may be a knob or meter that changes the amount of time that the flow meter is powered on to adjust the amount of time liquid may be poured through the flow meter on the power out 312.

The microchip 336 may include a processor for communicating signals within the UC 300 for performing control, and/or communicating signals with external devices. The processor on the microchip 336 may include one or more circuits, such as general purpose processors, special purpose processors, conventional processors, digital signal processors (DSPs), microprocessors, integrated circuits, a programmable logic device (PLD), application specific integrated circuits (ASICs), and/or the like. The processor may perform signal coding, data processing, power control, input/output processing, and/or any other functionality that enables the UC 300 to perform as described herein.

The microchip 336 may include memory for storing information on the UC 300. The processor on the microchip 336 may be in electrical communication with the memory. The processor may store information in and/or retrieve information from the memory. The UC 300 may store information on a non-removable memory and/or a removable memory. The non-removable memory may include random-access memory (RAM), read-only memory (ROM), a hard disk, and/or any other type of non-removable memory storage. The removable memory may include a subscriber identity module (SIM) card, a memory stick, a memory card (e.g., a digital camera memory card), and/or any other type of removable memory. The processor may access the memory for executable instructions and/or other information that may be used by the UC 300.

The microchip 336 may allow for communication with external devices. The processor on the microchip may be in electrical communication with a communication circuit for sending and/or receiving information. The communication circuit may be capable of performing wired and/or wireless communications. For example, the communication circuit may include a radio frequency (RF) transceiver for transmitting and receiving RF signals (e.g., BLUETOOTH®, near field communication (NFC), WIFI®, WI-MAX®, cellular, etc.) via an antenna, or other communications module capable of performing wireless communications. The memory may be connected to the antenna to send and receive data (e.g., a firmware update).

The microchip 336 may allow the UC 300 to communicate with an external database via the antenna. Information may be received from the master control device, such as a unique identifier (e.g., RFID), and the information may be compared with information received from the database. The RFID may be associated in the database with a given user or user account. The microchip 336 may identify information from the power provided to various devices and store the information in the external database. For example, the microchip 336 may identify that a certain amount of liquid has been poured out of the flow meter and store that information with the unique identifier (e.g., RFID) that is received.

The microchip 336 may control the relays through the optocouplers 322, 324. The optocouplers 322, 324 may isolate a control side of a respective relay (e.g., relay 326 or relay 328) from a load side of the relay. The control side of the relay may be a switch used to turn on or off the flow of electricity through the load side of the relay.

The UC 300 may include an RFID reader 302. Though an RFID reader 302 is illustrated, another RF communication device may be used. The RFID reader 302 may be attached to the UC 300 by use of a connector 334. The connector 334 may be, for example, a JST Connector. The connector 334 may be attached to programming pins 332 that communicate with the RFID reader 302 for receiving the RFID or other RF communications from the reader. The programming pins 332 may communicate the information to the microchip 336 for processing. The connector 334 may include clips that engage the programming pins to create connection the connection with the RFID reader 302. The RFID reader 302 may be replaceable. To replace the RFID reader, the connector 334 may be disconnected and another RFID reader 302 may be attached to the programming pins.

The RFID reader 302 may read a unique identifier from a master control device (not shown) (e.g., or another device) and may communicate the unique identifier to the processor on the microchip 336. The UC 300 may include an LED indicator 316, which may blink or glow to indicate a status of the UC 300. For example, the LED indicator 316 may continuously glow green to indicate that the UC 300 is powered and turned on. The LED indicator 316 may blink green to indicate that the UC 300 is receiving and/or installing a firmware update. The programming pins 332 may be used to program the UC 300 (e.g., by a bootloader). The programming pins 332 may allow one or more external devices to connect to the UC 300. The UC 300 may include one or more buttons, such as the flash button 304 and/or the reset button 306. The buttons 304, 306 may be used to perform a function on the UC 300. For example, one or more buttons may be pressed to program and/or reset the UC 300.

The UC 300 may include a Hall effect sensor (not shown). The Hall effect sensor may determine whether a magnet is within a pre-defined range of the UC 300 by measuring the magnitude of the magnetic field of the area surrounding the Hall effect sensor. For example, the Hall effect sensor may generate a voltage having a magnitude that is directly proportional to the strength of the magnetic field through the Hall effect sensor. The Hall effect sensor may determine that the magnet is within the pre-defined range of the UC 300 when the voltage exceeds a threshold value. The Hall effect sensor may be activated when an RFID tag located in a device (e.g., the master control device and/or a separate device) enters a pre-defined RF range of the RFID reader 302 and may be deactivated when the RFID tag leaves the pre-defined RF range. The UC 300 (e.g., the processor) may validate the RFID tag (e.g., the unique identifier associated with RFID tag) before the Hall effect sensor is activated. For example, the RFID tag may enter the pre-defined RF range of the RFID reader 302 and may transmit the unique identifier to the RFID reader 302, which may communicate the unique identifier to the processor on the microchip 336. The processor may validate the RFID tag, for example by comparing the unique identifier with a list of valid unique identifiers. The processor may activate the Hall effect sensor. If the RFID tag leaves the pre-defined RF range of the RFID reader 302, the processor may deactivate the Hall effect sensor.

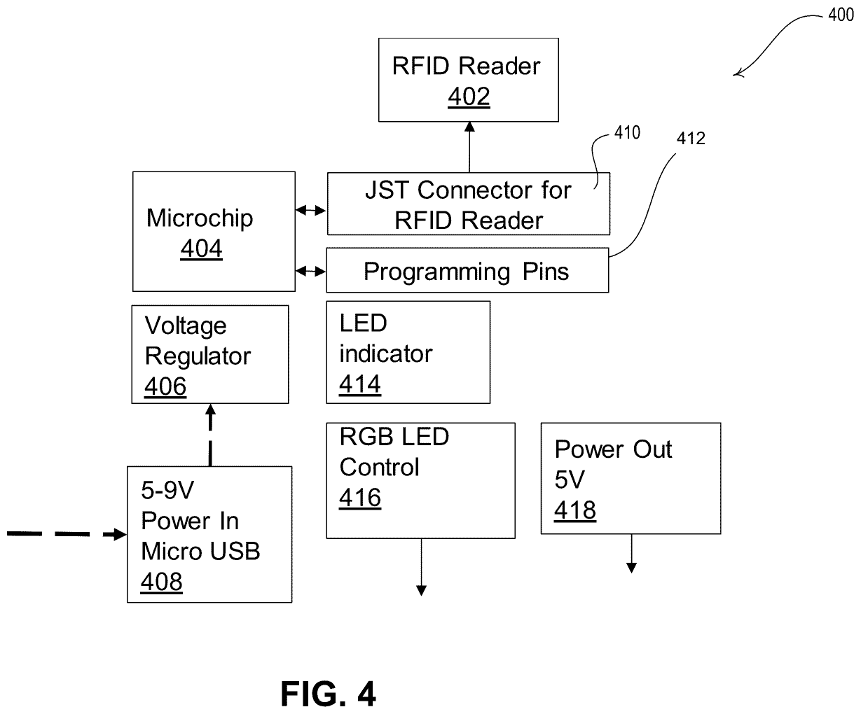

FIG. 4 shows a block diagram of an example a simple controller (SC) 400 (e.g., simple wand controller (SWC)). The SC 400 may be similar to the UC 300 illustrated in FIG. 3. The SC 400 may control an electrical object (e.g., a 5V object). For example, the SC 400 may control a lamp, and a master control device may control the lamp by sending a digital message to the SC 400 via RF communications (e.g., RFID, NFC, BLE, etc.) to turn the lamp on or off. The

SC 400 may be powered via a power input 408. The power input 408 may be, for example, a Micro USB or Qi wireless charging source. The power input 408 may receive 5V of power from the power source and may provide the power to a power output 418 (e.g., a 5V power output) for controlling one or more electrical loads (e.g., LEDs).

The power may pass through a voltage regulator 406. The voltage regulator 406 may drop the voltage, for example, from 5V to 3.3V. The regulated voltage may be used to power the microchip 404 and/or the RFID reader 402. The microchip 404 may include a processor and a memory, as described herein. The microchip 404 may be connected to an antenna that may be used to send and receive data (e.g., a firmware update, etc.) via RF communications as described herein. The microchip 404 may allow the SC 400 to communicate with external entities. For example, the microchip 404 may allow the SC 400 to access a database via the antenna. The SC 400 may include an RBG LED control output 416. The RGB LED control output 416 may be powered with 3.3V and may be used to power and/or control one or more LEDs.

The SC 400 may include an RFID reader 402, which may be attached to programming pins 412 of the SC 400 by use of a connector 412. The connector 412 may be a JST Connector as described herein. The RFID reader 402 may read a unique identifier from a master control device (not shown) and may communicate the unique identifier to the processor of the microchip 404 via the programming pins 412. The RFID reader 402 may be replaceable as described herein. The SC 400 may include an LED indicator 414, which may blink or glow to indicate a status of the SC 400 as described herein.

The SC 400 may include a Hall effect sensor (not shown). The Hall effect sensor may determine whether a magnet is within a pre-defined range of the SC 400 by measuring the magnitude of the magnetic field of the area surrounding the Hall effect sensor. For example, the Hall effect sensor may generate a voltage having a magnitude that is directly proportional to the strength of the magnetic field through the Hall effect sensor. The Hall effect sensor may determine that the magnet is within the pre-defined range of the SC 400 when the voltage exceeds a threshold value. The Hall effect sensor may be activated when an RFID tag located in a device (e.g., the master control device and/or a separate device) enters a pre-defined RF range of the RFID reader 402 and may be deactivated when the RFID tag leaves the pre-defined RF range. The SC 400 (e.g., the processor) may validate the RFID tag (e.g., the unique identifier associated with RFID tag) before the Hall effect sensor is activated. For example, the RFID tag may enter the pre-defined RF range of the RFID reader 402 and may transmit the unique identifier to the RFID reader 402, which may communicate the unique identifier to the processor on the microchip 404. The processor may validate the RFID tag, for example by comparing the unique identifier with a list of valid unique identifiers. The processor may activate the Hall effect sensor. If the RFID tag leaves the pre-defined RF range of the RFID reader 402, the processor may deactivate the Hall effect sensor.

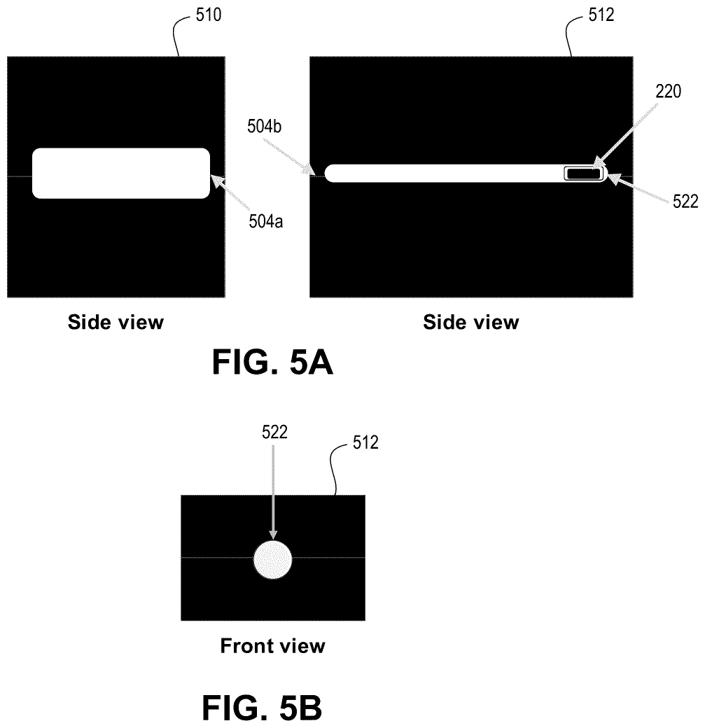

FIG. 5A illustrates a diagram of a cross-sectional side view of an example silicon mold that may be used for manufacturing the master control device. As shown in FIG. 5A, a recessed mold 510 of the handle of the master control device may be created. A recessed mold 512 of the shaft of the master control device may be created. The recessed mold may be a silicon mold. The control circuit 220 may be placed inside the recessed mold 512 at the end of the shaft portion of the master control device. The silicon mold 510 and the silicon mold 512 may be shaped with the recessed portions conforming to the lengths and diameters of the respective handle and shaft as described herein, such that the master control device may be created by filling the silicon molds 510, 512 with an appropriate liquid material (e.g., resin, plastic, and/or the like) via respective entry points 504a, 504b.

The liquid material may solidify in the silicon molds 510, 512 into the defined shapes. The control circuit 220 may be encapsulated in the shaft of the master control device as the liquid material solidifies. The silicon molds 510, 512 may be reusable. The silicon molds 510, 512 may each be in two or more sections, or may be a single mold. The portions of the master control device may be joined together after the liquid material has solidified.

FIG. 5B illustrates a diagram of a cross-sectional front view of the silicon mold 512 that may be used for manufacturing the master control device. The cross-sectional front view of the silicon mold 512 shows that the front tip 522 of the master control device encapsulates the control circuit 220.

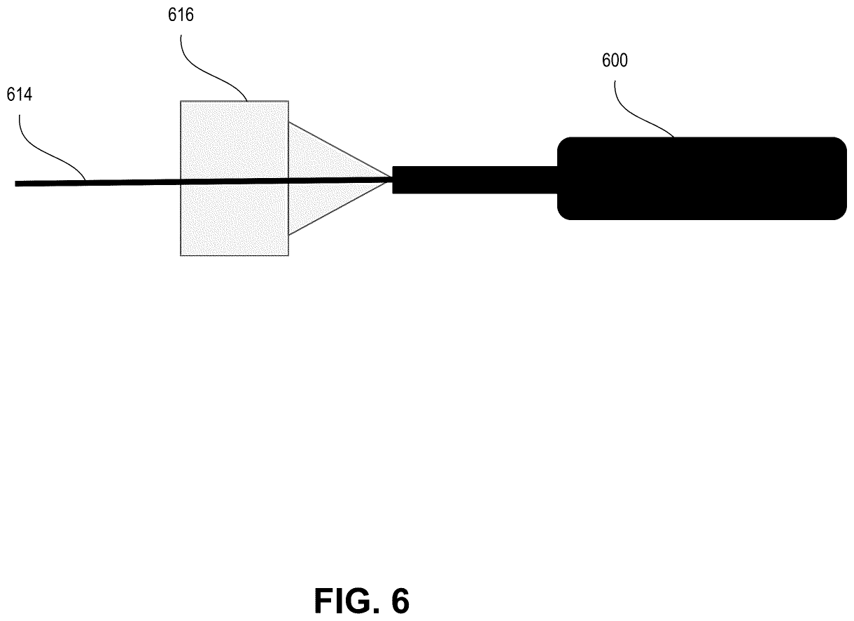

FIG. 6 illustrates a diagram of an example process for manufacturing a master control device 600 using a three-dimensional 3D printing technique. As shown in FIG. 6, the master control device 600, or portions thereof may be printed (e.g., 3D printed) in the configuration described herein. For example, material 614 may be melted and directed by nozzle 616 into the shape of the master control device 600. The material 616 may be, for example, a plastic, a resin, a wood/PLA composite, or any other suitable material. Nozzle 616 may be controlled by a computer (not shown) that may refer to or access a predetermined design, such as a design having the configurations described herein.

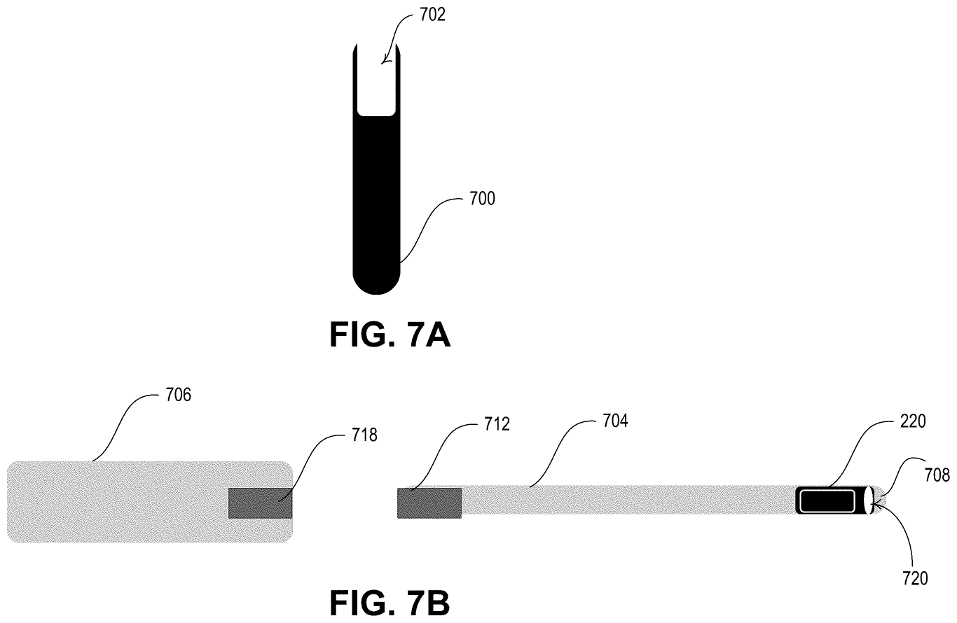

FIG. 7A illustrates a diagram of an example configuration for a distal end of the shaft of the master control device 700. The configuration illustrated in FIG. 7A may be performed using any of the manufacturing processes described herein. As illustrated in FIG. 7A, the distal end of the shaft of the master control device 700 may include an opening 702. The opening 702 may be approximately the size of the casing for the control circuit, such that the casing of the control circuit abuts each side wall of the opening 702. For example, the opening 702 may have a height within the range 12 mm to 23 mm and a diameter within the range 2.12 mm to 3.85 mm. The control circuit may be inserted into the opening 702 after the master control device 700 has been manufactured.

As shown in FIG. 7B, the master control device 700 may be formed in one piece or in multiple pieces that are later joined together. For example, handle 706 and shaft 704 may be formed separately. The handle 706 and the shaft 704 may be formed such that one section is able to be fastened to the other section using, for example, a screw, clasps, pins, and/or the like. The control circuit 220 may be positioned such that it is located on the end of the shaft 704 furthest from the handle 706.

The master control device 700 may be manufactured without the control circuit 220, and the control circuit 220 may be inserted into the master control device 700 after manufacturing of the master control device 700. The shaft 704 may have an opening 702 at one end following manufacturing of the master control device 700. The opening 702 may be of a size and shape that allows the control circuit 220 to be securely inserted into opening 702. For example, the opening 702 may have an internal length within the range 12 mm to 23 mm and a diameter within the range 2.12 mm to 3.85 mm. A distal end of the casing of the control circuit 220 may be approximately flush with the top portion of the opening 702, which may leave an exposed portion 720 of the casing of the control circuit 220. The exposed portion 720 of the casing of the control circuit 220 may be capped by filler 708 after the control circuit 220 has been inserted into opening 702. The filler 708 may be, for example, a liquid resin or glue that solidifies after it is applied to the exposed portion of casing 220. The filler 708 may be a cap that is fastened to the end of the shaft of the master control device 700 using, for example, a screw, clasps, pins, and/or the like.

As shown in FIG. 7B, the master control device 700 may manufactured in two or more separate parts that are later attached to each other. For example, the handle 706 and the shaft 704 may be manufactured separately. The handle 706 and the shaft 704 may be attached using a fastening mechanism, such as a screwing mechanism, a clasping mechanism, pins, and/or the like. For example, the handle 706 may include an attachment point 718 and the shaft 704 may include an attachment point 712. One of the attachment points 718, 712 may be female and the other may be male. Sections of the master control device 700 that are manufactured separately may be manufactured using different techniques. For example, handle 706 may be manufactured using a silicon mold and shaft 704 may be manufactured using 3D printing techniques, or vice versa.

FIG. 8A illustrates a diagram of an example control system 800 in which the master control device 802 may interact with a Universal Receiver (UR) 803 (e.g., a UWR) and/or a Universal Transmitter (UT) (not shown) to complete a specific action. The UR 803 may include or may interact with a UC 808 (e.g., a UWC) and/or an SC (e.g., an SWC). Master control device 802 may include control circuit 220, which may include a transponder (e.g., an RFID or NFC transmitter) with a unique identifier. The master control device 802 may be in the shape of a wand and may be held by a user. The user may tap or bring the end of the master control device 802, including the control circuit 220, within a wireless range of an antenna 804 for a microchip reader 806 (e.g., an RFID/NFC reader) to communicate with the microchip reader 806. The control circuit 220 may transmit the unique identifier to the microchip reader 806. The microchip reader 806 may send a digital message to the control circuit 220 to confirm receipt of the unique identifier via the antenna 804. The control circuit 220 may include an LED, which may blink when the master control device 802 comes into contact with, or within a wireless range of, the antenna 804. The master control device 802 may vibrate, shine, or otherwise indicate to the user that receipt of the unique identifier has been confirmed.

The control circuit 220 and reader 806 may be compatible both in frequency and standard. Tracking tags in the control circuit 220 may be made with the frequency and protocol compatible with the available RFID readers on the market. The tag in the control circuit 220 may operate at 13.56 mhz and may be a Ntag216 NFC and RFID compatible chip or any Ntag NFC and RFID compatible chip that runs at protocol ISO14443A/B. The tag may be, for example, 3.85 mm by 23 mm. The tag may be a high-frequency, passive tag that is compatible with the Mifare RC522, MF-RC522, RFID-RC522, and/or other readers operating at 13.56 mhz and protocol ISO14443A/B. The tag may be compatible with NFC readers of the same frequency and/or protocol.

The control circuit 220 may be readable and writeable, and the microchip reader 806 may be used to both receive data from the control circuit 220 and write data to the control circuit 220.

Upon receipt of the unique identifier, the microchip reader 806 may communicate with the UC 808 (e.g., as described herein). The microchip reader 806 may communicate with the UC 808 via a wired connection. The UC 808 may be connected to or otherwise associated with a controllable device 810. The controllable device 810 may be, for example, a light, a lock, a valve for a liquid, a valve for a gas, a magnetic stirrer, a fire starter/pilot light, a spark plug, and/or any other electronic device capable of performing an action. The UC 808 may be connected to a network 814 via a wireless connection (e.g., WiFi, Bluetooth, cellular, and/or the like). The network 814 may be, for example, a local wireless network.

One or more other devices may be connected to the UC 808 via the network 814. For example, the UC 808 may connect via the network 814 to a database 812 and/or one or more computing devices 816, 818. The database 812 may be running on, for example, a Raspberry Pi. Computing device A 818 may be located at the UR 803 for performing control, or at a remote location. The computing device A 818 may be, for example, a laptop/PC, and may be used for control and/or monitoring.

The UC 808 may access the database 812 via the network 814. The database 812 may store one or more associations between a unique identifier and an action to be performed upon receipt of the unique identifier from the master control device 802. For example, the controllable device 810 may be an electronic lock on a door. The database 812 may store an association between the unique identifier and locking the door (e.g., if the door is unlocked) or unlocking the door (e.g., if the door is locked). The UC 808 may retrieve the action associated with the unique identifier from the database 812 and may send a command to the controllable device 810 to perform the action.

The action that is performed may also be based on the location of the user. The location of the user may be determined from a computing device associated with the user (e.g., computing device B 816, which may be the user's mobile phone), or by the location at which the master control device 802 is being read by the microchip reader 806. For example, if the master control device 802 taps the antenna 804 located near a door and/or the UR 803, or component thereof, has an identifier in the database that is associated with a lock on a door, then the instruction may be sent to lock/unlock the door. If the antenna 804 is located near a light and/or the UR 803, or component thereof, has an identifier in the database that is associated with a light, control instructions may be generated for controlling the light.

The database 812 may include multiple possible actions for a single unique identifier. The UC 808 may determine which action to perform based on, for example, an identity of the controllable device 810, a quality and/or state of the controllable device 810, a time value, a location of the microchip reader 806, a number of taps of the master control device 802 against the microchip reader 806, and/or the like. For example, the controllable device 810 may be and/or may be associated with a valve (not shown) that controls the flow of a liquid (e.g., a drink). The user may hold the master control device 802 against the microchip reader 806 with the valve in the closed position. The UC 808 may receive the unique identifier and may identify from the database 812 that the action to be performed is to open the valve. The UC 808 may send a command to the controllable device 810 to open the valve. The UC 808 may keep the valve open as long as the master control device 802 is held against the microchip reader 806. The user may remove the master control device 802 from the microchip reader 806, and the UC 808 may send a command to the controllable device 810 to close the valve. Alternatively, if the controllable device 810 controls a light, the user may tap the master control device 802 against the microchip reader 806 once to turn on the light, remove the master control device 802 from the microchip reader 806 for a period of time, and tap the master control device 802 against the microchip reader 806 a second time to turn off the light. The database 812 may store more than one association (e.g., command) for the same unique identifier/controllable device pair, and the UC 808 may determine a command to send to the controllable device 810 based on a state of the controllable device 810. For example, the UC 808 may command the controllable device 810 to turn on the light if the light is off and may command the controllable device 810 to turn off the light if the light is on. The controllable device 810 may also be used to activate a magnetic stirring mechanism, a motor, a lock, a water vaporizer, a fog machine, a pump, a linear actuator, an auger, a servo, a speaker, or a microcontroller.

The unique identifier received from the master control device 802 may be associated with the name of the user in the database 812. The database 812 may include a Boolean variable for each unique identifier indicating whether the master control device 802 associated with the unique identifier is active. A unique identifier may be marked as active when the master control device 802 is assigned to a user, and marked as inactive when the user returns the master control device 802.

The computing device A 818 may be used to monitor and/or control the reception of the unique identifier, the accessing of the database 812, and the performing of the action. The computing device A 818 may be connected to a router for a local network 820. Computing device A 818 may be the location at which the database 812 is stored, and may be the access point for the local wireless network 814. For example, the computing device A 818 may log the reception of the unique identifier and the performing of the action. The computing device A 818 may log a number of times that the action is performed, an amount of time between performing two actions, and/or a number of distinct unique identifiers received. For example, the controllable device 810 may be and/or may be associated with a valve (not shown) that controls the flow of a liquid (e.g., a solenoid valve controlling the flow of a drink). The user may hold the master control device 802 against the microchip reader 806 to open the valve and remove the master control device 802 from the microchip reader 806 to close the valve.

The computing device A 818 may measure an amount of time that the valve was open, which may be directly proportional to the amount of liquid dispensed. In another example, the controllable device 810 may be a flow meter that may directly measure the amount of liquid poured and communicate that amount (e.g., via the UR 803) to the computing device A 818. The controllable device 810 may include multiple different taps from which different liquids may be dispensed and the amount from each tap may be measured by a flow meter and communicated back to the computing device A 818. In another example, the controllable device 810 may be a peristaltic pump or pumps that measures the time and/or rotations of the pump to determine the volume of liquid that has been dispensed.

It may be difficult to determine the amount of liquid dispensed from each pressurized tap in a pressurized system. When the controllable device 810 includes a flow meter, the amount of liquid being dispensed from each tap may be calculated and the amount of pressure may be adjusted to optimize the system.

The computing device A 818 may determine an amount of money owed by the user based on the amount of liquid dispensed. The computing device A 818 may communicate information to the database 812, the microchip reader 806, the master control device 802, and/or computing device B 816 via the network 814. As different liquids may have a different cost and/or pressure associated therewith, the computing device A 818 may associate the cost and/or pressure for each liquid dispensed from controllable device 810. The computing device B 816 may obtain information from the database 812, UC 808, and/or computing device A 818 via the network 814, and may display or otherwise use the information.

FIG. 8B illustrates a diagram of an example control system 830 in which the system 800 may be integrated with a smart device 822 (e.g., a home assistant). For example, the system 830 may be similar to the system 800 shown in FIG. 8A (e.g., with the addition of a smart device). Referring to FIG. 8B, the UC 808 may communicate with the smart device 822 via a wired connection and/or a wireless connection. The smart device 822 may include an integrated microphone, external sound card, and/or an integrated speaker.

The smart device 822 may be equipped with a voice recognition API. The smart device may use the integrated microphone to listen for a specific word or command. There may be a phrase associated with the UC 808 that, when received by the UC 808, causes the UC 808 to send a command to a controllable device 810. The user of the master control device 802 may say the phrase. The smart device 822 may receive the phrase via the microphone and perform voice recognition. If the smart device 822 determines that the user spoke the phrase associated with the UC 808, the smart device 822 may send an indication to the UC 808 that the correct phrase was spoken. Upon receipt of the indication, the UC 808 may send a command to the controllable device 810 to perform an action associated with the phrase.

FIG. 8C illustrates a diagram of an example control system 850 in which the master control device 802 may interact with a universal receiver (UR) 803 (e.g., a UWR) via a tip component (e.g., the magnet 221). The UR 803 may include, for example, a Hall effect sensor 807, a universal controller (UC) 808, a microchip reader 806, and/or an antenna 804. The UR 803 may interact with the master control device 803 (e.g., via the Hall effect sensor 807) and an RFID tag 805 (e.g., via the antenna 804). The RFID tag 805 may be located in a separate device, which may be in the shape of an amulet. The RFID tag 805 may be associated with a unique identifier. The UR 803 may include or may interact with a UC 808 (e.g., a UWC) and/or an SC (e.g., an SWC). The master control device 802 may include the magnet 221. For example, the magnet 221 may be part of the control circuit 220 shown in FIG. 8A. The master control device 802 may be in the shape of a wand and may be held by a user.

The RFID tag 805 may be brought within a read range (e.g., a pre-defined RF range) of the antenna 804. The antenna 804 may then communicate with the microchip reader 806. For example, the RFID tag 805 may transmit the unique identifier to the microchip reader 806 via the antenna 804. The microchip reader 806 may send a digital message to the UC 808 to confirm receipt of the unique identifier via the antenna 804. The UC 808 may validate the unique identifier, and may activate the Hall effect sensor 807. The user may then tap or bring the end of the master control device 802, including the magnet 221, toward the Hall effect sensor 807 to communicate with UC 808. For example, the Hall effect sensor 807 may detect the magnetic field of the magnet 221 and transmit an indication to the UC 808 that the magnet 221 has been detected. Upon reception of the indication from the Hall effect sensor 807, the UC 808 may command a controllable device (e.g., the controllable device 810) to complete a programmed action (e.g., while the Hall effect sensor is detecting the magnet 221 and/or for a predetermined period of time after the Hall effect sensor detects the magnet 221).

In an example, the RFID tag 805 may be located within a separate device. The RFID tag 805 may be associated with a unique identifier, which may be assigned to a user. The user of the RFID tag 805 (e.g., the user of the master control device 802) may bring the RFID tag 805 within a pre-defined RF range of the UR 803. For example, the RFID tag 805 may be located within a device having the shape of an amulet or other object, and the user may place the amulet or other object in a slot that is located within the pre-defined RF range. Once the RFID tag 805 enters the pre-defined RF range, the RFID tag may transmit the unique identifier to the UR 803 (e.g., via the antenna 804). The UR 803 may receive the unique identifier and may validate the unique identifier, for example by comparing the unique identifier with a list of valid unique identifiers. The list of valid unique identifiers may be located on a memory of the UC 808 and/or in the database 212. For example, the UC 808 may compare the unique identifier with a registered unique identifier of a user stored in the database 812 to determine that the unique identifier is registered to a user in the system. In response to the UC 808 receiving the unique identifier and/or determining that the unique identifier has been registered to a user, the UC 808 may activate or turn on the Hall effect sensor 807. The Hall effect sensor 807 may remain activated while the RFID tag 805 is within the pre-defined RF range of the UR 803, and may deactivate when the RFID tag 805 leaves the pre-defined RF range. The Hall effect sensor 807 may determine whether a magnet has entered within a pre-defined range of the UR 803. For example, the magnet may be the magnet 221 in the master control device 802.

The user of the master control device 802 may bring the magnet 221 within the pre-defined range of the UR 803 (e.g., the Hall effect sensor 807). The Hall effect sensor 807 may measure the magnitude of the magnetic field of the area around the Hall effect sensor 807, and may determine that the magnet 221 is within the pre-defined range when the magnitude exceeds a threshold value. When the Hall effect sensor 807 determines that the magnet 221 is within the pre-defined range, the Hall effect sensor 807 may send an indication to the UC 808. Upon reception of the indication, the UC 808 may transmit a command to the controllable device 810 to perform an action. The Hall effect sensor 807 may continuously transmit the indication while the magnet 221 is within the pre-defined range. Alternatively, the Hall effect sensor 807 may transmit the indication a predetermined number of times when the magnet 221 enters the pre-defined range, and may not transmit the indication again until the magnet 221 leaves and re-enters the pre-defined range. The UC 808 may command the controllable device 810 to perform the action continuously while the magnet 221 is within the pre-defined range of the Hall effect sensor 807 and the RFID tag 805 is within the pre-defined RF range of the UR 803. Alternatively, the UC 808 may command the controllable device 810 to perform a predefined action, the action a predetermined number of times and/or for a predetermined amount of time after receiving the indication from the Hall effect sensor 807. The controllable device 810 may communicate with the UC 808 via a wired and/or wireless connection.

The UC 808 may create an association between the action and the unique identifier of the RFID tag 805, and may store the association in the database 812. For example, if the controllable device 810 is a system that dispenses a drink, the UC 808 may associate an amount of the drink that was dispensed and/or an amount of time that the drink was dispensed with the unique identifier. In another example, if the controllable device 810 is a system that vends food or drink (e.g., a vending machine), the UC 808 may associate a type and/or price of the purchased item and the unique identifier.

The controllable device 810 may be, for example, a system that dispenses a drink. The controllable device 810 may dispense the drink while the magnet 221 is within the pre-defined range and the RFID tag 805 is within the pre-defined RF range. Alternatively, the controllable device 810 may dispense the drink for a predetermined amount of time, or the controllable device 810 may dispense a predetermined amount of the drink.

In other examples, the controllable device 810 may be a vending machine, a smart plug, a lock, a light, a valve for a liquid, a valve for a gas, a magnetic stirrer, a fire starter/pilot light, a spark plug, and/or any other electronic device capable of performing an action. For example, if the controllable device 810 is a lock, the UC 808 may send a command to the lock to lock or unlock when the RFID tag 805 enters the pre-defined RF range of the UR 803 and the magnet 221 enters within the pre-defined range of the Hall effect sensor 807. Alternatively, if the controllable device 810 is a light, the UC 808 may send a command to the light to turn on or off when the RFID tag 805 enters the pre-defined RF range of the UR 803 and the magnet 221 enters within the pre-defined range of the Hall effect sensor 807 or is otherwise detected by the Hall effect sensor 807.

The control system 850 may include more than one controllable device. Each controllable device may be connected to a separate UR. Alternatively, one or more controllable devices may be connected to the same UR. The UR may include one or more antennas and/or Hall effect sensors (e.g., one for each controllable device). Each antenna may be connected to a given Hall effect sensor. An indication sent from a given Hall effect sensor may include an identifier associated with the Hall effect sensor, and the UR may determine which controllable device to send a command based on the identifier.

FIG. 8D illustrates a diagram of an example control system 870, in which the system 850 may be integrated with the smart device 822 (e.g., a home assistant). For example, the system 870 may be similar to the system 850 shown in FIG. 8C (e.g., with the addition of the smart device 822). Referring to FIG. 8D, the UC 808 may communicate with the smart device 822 via a wired connection and/or a wireless communication protocol. The smart device 822 may include an integrated microphone, external sound card, and/or an integrated speaker.

For example, as described above, a user of the master control device 802 may bring the RFID tag 805 within a pre-defined RF range of the UR 803 (e.g., the antenna 804), which may activate the Hall effect sensor 807. The user may bring the magnet 221 within a pre-defined range of the Hall effect sensor 807. The Hall effect sensor 807 may detect the magnetic field generated by the magnet 221, and may transmit an indication to the UC 808 that the magnetic field was detected. When the UC 808 receives the indication, the UC 808 may send a message to the smart device 822 to begin listening for a word or phrase associated with the UC 808. Alternatively, the smart device 822 may be continuously listening for the word or phrase associated with the UC 808. Once the smart device 822 hears the word or phrase, the smart device 822 may send an indication to the UC 808. The smart device 822 and/or the UC 808 may look up an association between the word or phrase and an action to be performed by a controllable device (e.g., or a command that instructs the controllable device to perform the action). For example, the smart device 822 and/or the UC 808 may access a database (e.g., the database 812) or an API which has one or more associations stored thereon. The UC 808 may then transmit a command to the controllable device 810 to perform the action associated with the word or phrase.

For example, the controllable device 810 may be a system that dispenses a drink. After the UC 808 determines that the magnet 221 is within the pre-defined range and the RFID tag 805 is within the pre-defined RF range, the UC 808 may send an indication to the smart device 822 to listen for the phrase “pour drink.” The user may say the phrase “pour drink,” and the smart device 822 (e.g., microphone of the smart device 822) may hear the user say the phrase. The smart device 822 may send an indication to the UC 808 that the user said the phrase “pour drink.” The UC 808 may access the database 812 in order to determine an action associated with the phrase “pour drink.” The UC 808 may determine that the action associated with the phrase is dispensing a drink. The UC 808 may then send a command to controllable device 810 that instructs the controllable device 810 to dispense the drink.

In other examples, the controllable device 810 may be a vending machine, a smart plug, a lock, a light, a valve for a liquid, a valve for a gas, a magnetic stirrer, a fire starter/pilot light, a spark plug, and/or any other electronic device capable of performing an action. For example, if the controllable device 810 is a lock, the UC 808 may send a command to the lock to unlock when the RFID tag 805 enters the pre-defined RF range of the UR 803, the magnet 221 enters within the pre-defined range of the Hall effect sensor 807, and the smart device 822 hears the word “unlock.” Alternatively, if the controllable device 810 is a light, the UC 808 may send a command to the light to turn on when the RFID tag 805 enters the pre-defined RF range of the UR 803, the magnet 221 enters within the pre-defined range of the Hall effect sensor 807 or is otherwise detected by the Hall effect sensor 807, and the smart device 822 hears the phrase “light on.”

FIG. 8E illustrates a diagram of an example control system 1800 in which the master control device 802 may interact with a universal transmitter (UT) 1804 via a tip component (e.g., the magnet 221). The UT 1804 may include, for example, a Hall effect sensor 1810, a transmitter (e.g., a 433 MHz transmitter) 1812, an LED 1814, a charging circuit 1816, and/or a battery (e.g., a Li-ion battery) 1818. The UT 1804 may interact with the master control device 802 (e.g., via the Hall effect sensor 1810) and a smart socket 1806. The smart socket 1806 may include a receiver (e.g., a 433 MHz receiver) 1820, a mains socket 1822, and/or a control circuit (not shown). The mains socket 1822 may be configured to receive a connector (e.g., a plug) of a controllable device, and may provide power to the controllable device. The smart socket 1806 may be configured to plug into an outlet. The master control device 802 may include the magnet 221. For example, the magnet 221 may be part of the control circuit 220 shown in FIG. 8A. The master control device 802 may be in the shape of a wand and may be held by a user.

The UT 1804 and/or the smart socket 1806 may each include respective buttons (not shown) that, when pressed for at least a predetermined amount of time, may cause the UT 1804 and/or the smart socket 1806 to enter a pairing mode. For example, while in the pairing mode, the UT 1804 may broadcast a wireless signal that includes a unique identifier of the UT 1804 and may listen for another wireless signal that includes a unique identifier of the smart socket 1806. Similarly, while in the pairing mode, the smart socket 1806 may broadcast a wireless signal that includes a unique identifier of the smart socket 1806 and may listen for another wireless signal that includes a unique identifier of the UT 1804. Once the UT 1804 and/or the smart socket 1806 receives the unique identifier of the other device, the UT 1804 and/or the smart socket 1806 may pair with the other device, transmit a message to the other device indicating that the UT 1804 and/or the smart socket 1806 has paired with the other device, and may exit the pairing mode. Once the other device receives the message, the other device may pair with the UT 1804 and/or the smart socket 1806 and may exit the pairing mode. The LED 1814 may light and/or blink to indicate that the UT 1804 is in the pairing mode. Similarly, an LED associated with the smart socket 1806 (not shown) may light and/or blink to indicate that the smart socket 1806 is in the pairing mode.

In an example, a user of the master control device 802 may press the button on the UT 1804 for a predetermined amount of time to cause the UT 1804 to enter the pairing mode. The LED 1814 may light and/or blink to indicate that the UT 1804 is in the pairing mode, and the UT 1804 may begin broadcasting a wireless signal that includes the unique identifier of the UT 1804. The UT 1804 may begin listening for a wireless signal that includes the unique identifier of the smart socket 1806. The user may then press the button on the smart socket 1806 for the predetermined amount of time to cause the smart socket 1806 to enter the pairing mode. The LED associated with the smart socket 1806 may light and/or blink to indicate that the smart socket 1806 is in the pairing mode, and the smart socket 1806 may begin broadcasting a wireless signal that includes the unique identifier of the smart socket 1806. The smart socket 1806 may begin listening for a wireless signal that includes the unique identifier of the UT 1804.

The UT 1804 may receive the signal that includes the unique identifier of the smart socket 1806, pair with the smart socket 1806, transmit a message to the smart socket 1806 indicating that the UT 1804 has paired with the smart socket 1806, and exit the pairing mode. The smart socket 1806 may receive the indication from the UT 1804, pair with the UT 1804, and exit the pairing mode. Additionally and/or alternatively, the smart socket 1806 may receive the signal that includes the unique identifier of the UT 1804, pair with the UT 1804, transmit a message to the UT 1804 indicating that the smart socket 1806 has paired with the UT 1804, and exit the pairing mode. The UT 1804 may receive the indication from the smart socket 1806, pair with the smart socket 1806, and exit the pairing mode.

Once the UT 1804 and the smart socket 1806 are paired, the user may tap or bring the end of the master control device 802, including the magnet 221, toward the Hall effect sensor 1810 of the UT 1804. The Hall effect sensor 1810 may detect the magnetic field of the magnet 221, and may transmit an indication to the smart socket 1806 that the magnet 221 has been detected via the 433 MHz transmitter 1812. The UT 1804 and the smart socket 1806 may be physically separated from each other, and may communicate via RF signals. For example, the UT 1804 and the smart socket 1806 may communicate via a wireless communication protocol (e.g., Wi-Fi, Bluetooth Low Energy (BLE), Zigbee, etc.).

Upon reception of the indication from the UT 1804, the control circuit of the smart socket 1806 may cause a controllable device 1808 that is plugged into the mains socket 1822 to complete a programmed action. For example, the control circuit of the smart socket 1806 may command the controllable device 1808 to transition from a first state to a second state, or from the second state to the first state. For example, the control circuit of the smart socket 1806 may command the controllable device 1808 to turn off or on. The LED 1814 of the UT 1804 may be used to represent a current state of the controllable device 1808. For example, if the controllable device 1808 is currently in an off state, the LED 1814 may also be off, while if the controllable device 1808 is currently in an on state, the LED 1814 may also be on. In another example, the LED 1814 may light in a first color to represent the controllable device 1808 being in the first state and in a second color to represent the controllable device 1808 being in the second state. Alternatively, the LED 1814 of the UT 1804 may turn on when the magnet 221 is within a pre-defined range of the Hall effect sensor 1810 and may turn off when the magnet 221 leaves the pre-defined range of the Hall effect sensor 1810.

The controllable device 1808 may be any device that receives power from a mains socket. For example, the controllable device 1808 may be a lamp, a television, an appliance, a gaming console, etc. In another example, the controllable device 1808 may be a smart home device (e.g., the smart device 822), and the programmed action may be entering an active/listening state.

As described herein, the UT 1804 may transmit a message to the smart socket 1806 when a triggering event occurs. For example, the triggering event may be touching the tip of the master control device 802 to the UT 1804 once, touching the tip of the master control device 802 to the UT 1804 a predefined amount of times (e.g., two) within a predetermined amount of time, touching the tip of the master control device 802 to the UT 1804 and holding it there for a predetermined amount of time, etc.

Upon detection of the triggering event, the UT 1804 may generate a message that includes a command to perform an action. For example, the action may be to change a state of the controllable device 1808 and/or to change an amount of power provided to the controllable device 1808. For example, the action may be to turn the controllable device 1808 on or off, change an output provided by the controllable device 1808 (e.g., change the color output of a lamp, play a different song on a speaker, change the channel of a television, etc.), change an intensity of output provided by the controllable device 1808, put the controllable device into an active/listening mode, etc. The smart socket 1806 may receive the message and may perform the action indicated in the command.

In an example, the controllable device 1808 may be a lamp (e.g., a lighting control device), and the master control device 802 may be used to turn the lamp on or off. For example, the user may touch the tip of the master control device 802 to the UT 1804 a first time to turn the lamp on, and a second time to turn the lamp off. Alternatively, the master control device 802 may be used to change a color of light output by the lamp. For example, the lamp may cycle through a predefined list of colors (e.g., yellow, green, blue, red, yellow, green, etc.) each time the user touches the tip of the master control device 802 to the UT 1804. Alternatively, the master control device 802 may be used to change an intensity of the light output by the lamp. For example, the user may hold the tip of the master control device 802 against the UT 1804 to increase or decrease the intensity of the light output by the lamp.

In another example, the controllable device 1808 may be a smart home device (e.g., the smart device 822), and the master control device 802 may be used to cause the smart home device to enter an active/listening state. For example, the user may use the master control device 802 to cause the smart home device to enter the active/listening state in addition to or as an alternative to a spoken phrase. The smart home device may remain in the active/listening state while the user is touching the tip of the master control device 802 to the UT 1804. Additionally and/or alternatively, the smart home device may enter the active/listening state when the user touches the tip of the master control device 802 to the UT 1804, and may remain in the active/listening state for a predetermined amount of time (e.g., regardless of whether the user is continuing to touch the tip of the master control device 802 to the UT 1804).

In another example, the controllable device 1808 may be a system for dispensing a drink (e.g., as described herein), and the master control device 802 may be used to cause the system to dispense a drink. For example, as described herein, the system may dispense the drink while the user is touching the tip of the master control device 802 to the UT 1804, and may stop dispensing the drink once the user removes the tip of the master control device 802 from the UT 1804. Additionally and/or alternatively, the system may begin dispensing the drink when the user touches the tip of the master control device 802 to the UT 1804, and may continue to dispense the drink for a predetermined amount of time and/or until the system has dispensed a predefined amount of the drink.

In another example, the controllable device 1808 may be an output device. For example, the controllable device 1808 may be a television, a speaker, a gaming console, etc, and the master control device 802 may be used to turn the output device on or off. Additionally and/or alternatively, the master control device 802 may be used to cause the output device to provide a predetermined output. For example, the controllable device 1808 may be a speaker, and the speaker may produce a predetermined sound when the user touches the tip of the master control device 802 to the UT 1804. Alternatively, the speaker may begin playing music when the user touches the tip of the master control device 802 to the UT 1804 a first time, and may skip to a next song or track when the user touches the tip of the master control device 802 to the UT 1804 a second time.

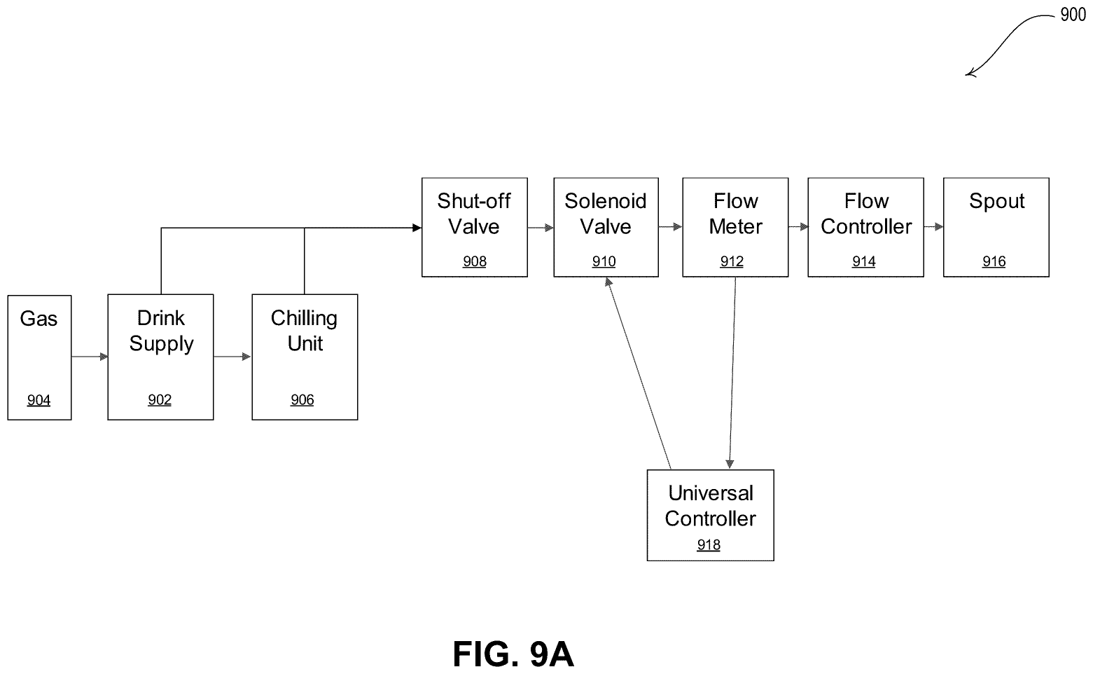

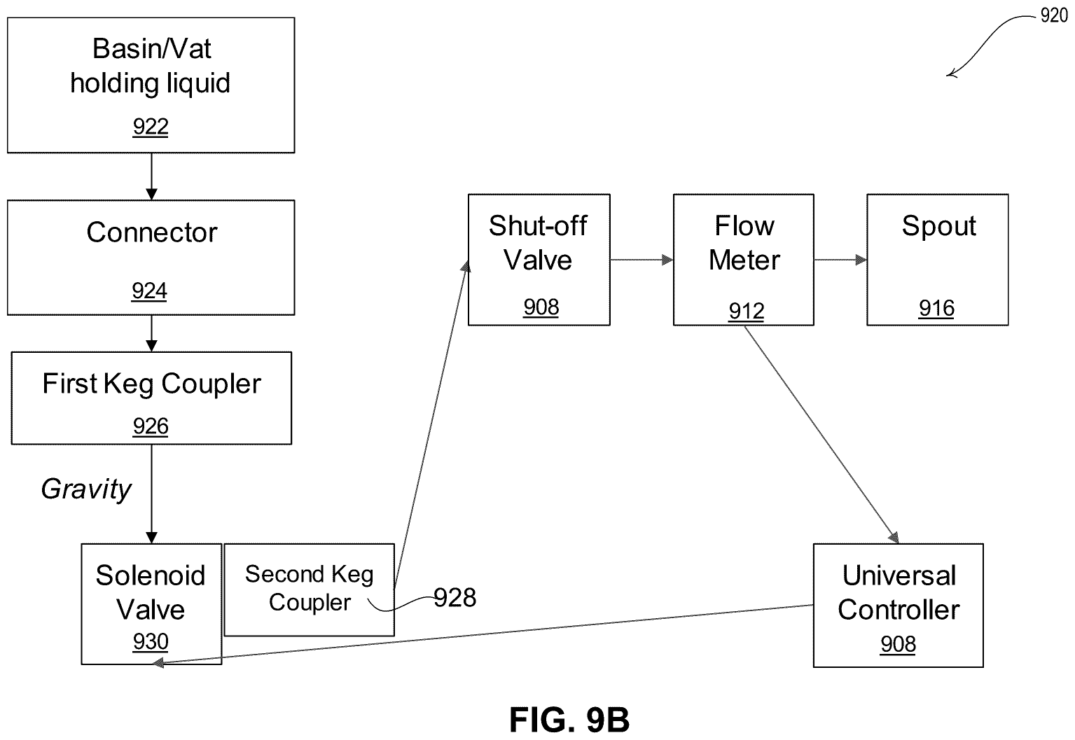

FIG. 9A illustrates a diagram of an example system 900 in which the UC 918 may be used to dispense a drink with gas based on an RF communication from a master control device (not shown). For example, the drink may be beer, and the master control device may be located in a bar or other serving area. The unique identifier received from the master control device may be associated with the name of the user in a database (not shown).

There may be a supply 902 of the drink, which may be connected to a supply of gas 904. For example, the drink may be in a keg, which may be connected via a gas line to a supply of gas 904. The drink supply 902 may be connected to a valve 908 (e.g., a shut-off valve) via a product line. The drink may be provided to the valve 908 via a chilling unit 906, which may be used to decrease the temperature of the drink. The drink may bypass the chilling unit 906.

The shut-off valve 908 may be used to stop the flow of the drink, for example, if an electric circuit or other device fails. The drink may flow from the shut-off valve 908 through a second valve 910 (e.g., a solenoid valve). The solenoid valve 910 may be controlled by a UC 918 (e.g., a UWC). The UC 918 may be connected to one or more other devices (e.g., as shown in FIG. 8A). The UC 918 may receive the unique identifier from the master control device and send a command to perform an action as described herein.

The solenoid valve 910 may be connected to a flow meter 912, which may monitor the flow of the liquid as it is dispensed via a spout 916. For example, the flow meter 912 may monitor the speed of the liquid flow. There may be a flow controller 914 between the solenoid valve 910 and the spout 916. The flow controller 914 may restrict the flow of the liquid. For example, less liquid may pass through the spout 916 if the flow controller 914 is tighter. The solenoid valve 910 may open to dispense the drink and close to stop dispensing the drink, for example upon receiving a command from the UC 918. There may be a flow meter 912 that measures the amount of drink dispensed. The flow meter 912 may measure the amount of drink dispensed directly and/or indirectly. For example, the flow meter 912 may measure a number of rotations of a motor associated with the flow meter 912, and determine the amount of drink dispensed based on the amount of rotations.

The flow meter 912 may send information about the amount of drink dispensed to the UC 918. The UC 918 may send the information to the database, which may store associations between the type or brand of the drink and the amount of drink dispensed. The database may also store, for example, the number of times and the duration that the user used the master control device or information regarding an instance of the use of the master control device. The information about the amount of drink dispensed to the user may be used to determine an amount of money charged to the user for the drink and/or the pressurization of the particular drink being dispensed. The amount of money and/or pressurization information may be stored in the database and associated with the user. The database may store multiple transactions for a single user (e.g., one amount for each time the user dispenses a drink), or multiple amounts may be added together and stored as a single total for the user. Any further amounts charged to the user may be added to the total. The UC 918 may connect to a computing device B (not shown) from which information in the database (e.g., the charges owed by a given user) may be read, displayed, and/or printed.

FIG. 9B illustrates a diagram of an example system 920 in the master control device may be used to dispense a drink using gravity. The example depicted in FIG. 9B may be similar to the example depicted in FIG. 9A. Referring to FIG. 9B, the drink may be held within a basin 922 (e.g., a vat). The basin 922 may be connected via a connector 924 to a first keg coupler 926. The connector 924 may be configured such that it is able to connect the basin 922 to the first keg coupler 926. The first keg coupler 926 may be, for example, a ⅜″ John Guest keg coupler. The first keg coupler 926 and the connector 924 may attach the basin 922 to a solenoid valve 930. The solenoid valve 930 may be a “direct acting” solenoid valve. For example, the solenoid valve 930 may use gravity to allow liquid to pass through freely. The solenoid valve 930 may be the same as solenoid valve 910 described in FIG. 9A.

Referring again to FIG. 9B, the basin 922 may be at a higher elevation than the solenoid valve 930, such that when the solenoid valve 930 is opened, the liquid is dispensed via gravity. The solenoid valve 930 may be connected to a second keg coupler 928. The second keg coupler 928 may be connected to a lower end of the solenoid valve 930 (e.g., opposite the first keg coupler 926). The second keg coupler 928 may be connected to the flow meter 912 and the spout 916 via the shut-off valve 908. The flow meter 912, spout 916, and shut-off valve 908 may perform as described in FIG. 9A. The flow meter 912 and solenoid valve 930 may be connected to the UC 908, which may interact with the flow meter 912 and the solenoid valve 930 as described in FIG. 9A.

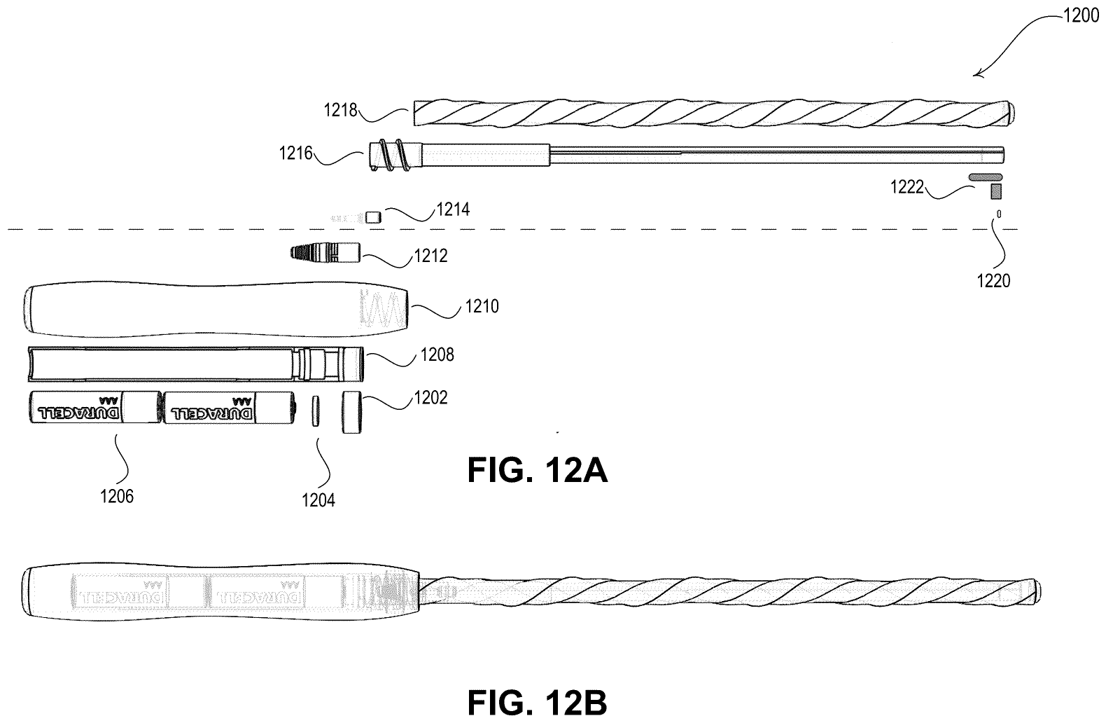

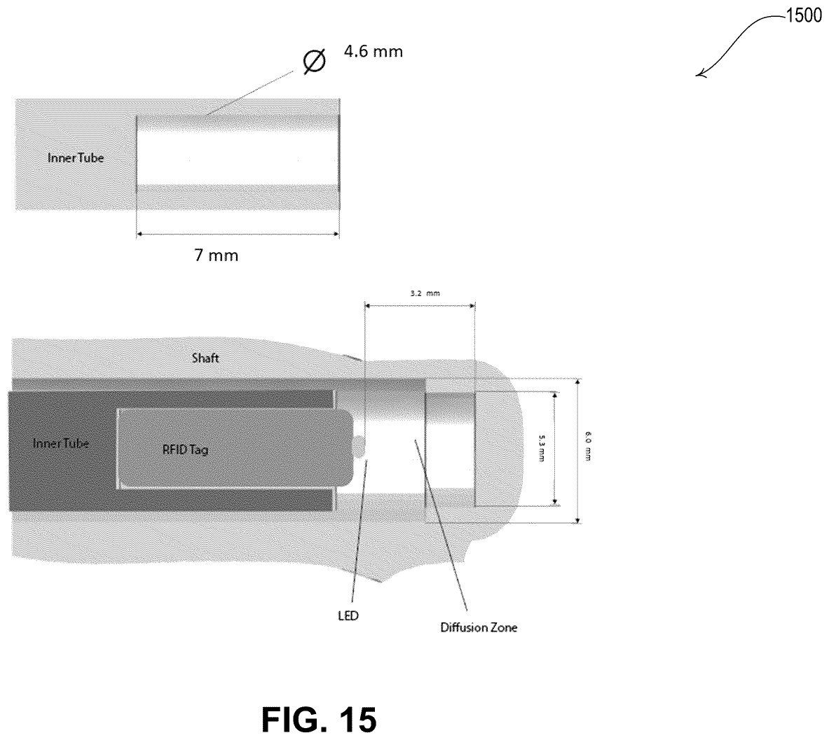

A master control device may include an LED (e.g., the LED 105 shown in FIG. 1, the LED 1220 shown in FIGS. 12A, 13A, 14A and/or 17A, and/or the LED shown in FIG. 15), which may be housed in the tip of the master control device. The LED may turn on when a user of the master control device touches a defined portion of a touch-responsive area (e.g., a capacitive touch zone) on the master control device. The LED may remain on as long as the user is touching the touch-responsive area (e.g., when a predefined portion of the touch-responsive area is covered by the user's hand) and/or until the LED reaches a maximum on time. The LED may turn off when the user stops touching the defined portion of the touch-responsive area and/or when the LED reaches the maximum on time. The LED may remain off while there is no user input (e.g., in the form of touch). The touch-responsive area may be created by, for example, an electrode (e.g., a copper ring), which may act as a sensor amplifier. The electrode may create a 360-degree capacitive touch zone, which may be in the shape of a ring on the outside of the master control device. A master control device may have a weight of, for example, approximately 68±7 grams.

As used herein, the term “touch” and variants thereof may include a physical connection between the master control device and the user of the master control device. For example, the touch-responsive area may be created via a capacitance coil located within the master control device, which may increase capacitance in the master control device. The capacitance coil may be, for example, a copper ring (e.g., copper adhesive tape). Using a copper ring may allow for control of the sensitivity of the touch-responsive area (e.g., depending on the width, thickness, and/or number of rotations of the ring) around the entire circumference of the master control device. For example, the sensitivity may depend on the material used in the master control device and/or the thickness thereof.

The master control device may be manufactured such that any components (e.g., electrical components) located within the master control device are not visible. For example, the master control device may be 3D printed or made from a mold or cast. A portion of the master control device (e.g., or an outer housing thereof) may be printed, molded, and/or cast. After the portion of the master control device is printed, the electrical components may be attached to (e.g., inserted into) the printed portion. After the electrical components are attached, a remaining portion of the master control device may be printed around the electrical components (e.g., such that there is no access to the electrical components). The electrical components may also be attached to a 3D printed or cast inner tubing that may be placed inside the two halves of the master control device. The two halves of the master control device may be screwed together around the inner tubing.

One or more components (e.g., electrical components) used in the master control device may be manufactured and/or designed such that the components may be attached to the master control device during printing. For example, the components may together form an internal assembly. The diameter and/or length of the internal assembly may be minimized. The internal assembly may be radially symmetrical and/or linearly tapered (e.g., thinner at the base than at the top) such that the internal assembly may slide into the printed portion of the master control device. The components may be designed such that one or more components have similar shapes and/or sizes. For example, a PCB used in the master control device may have a circular design, and may be designed to have the same diameter as one or more batteries used in the master control device.

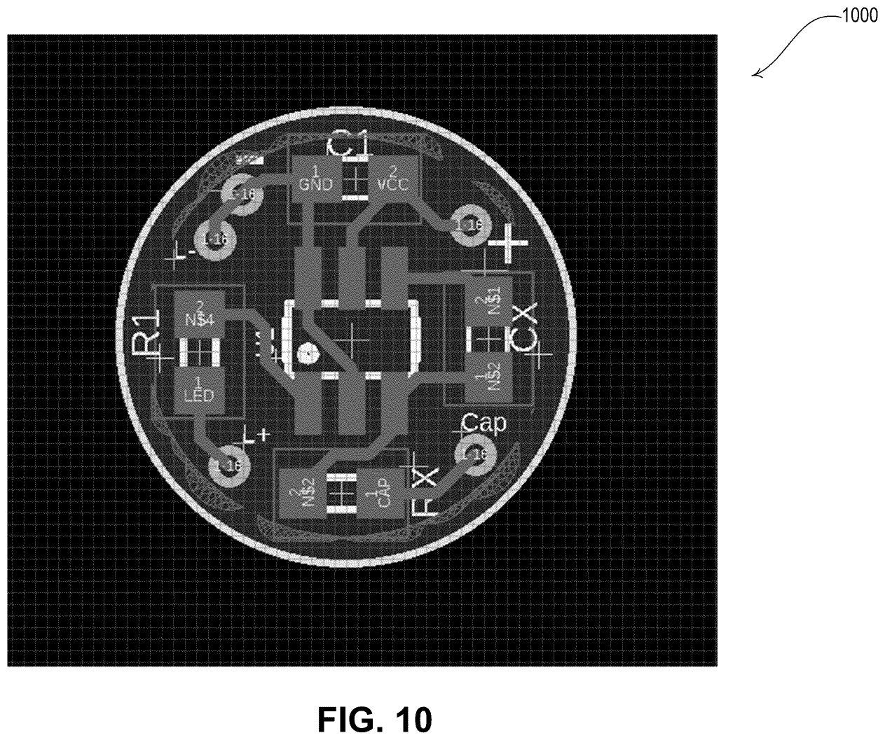

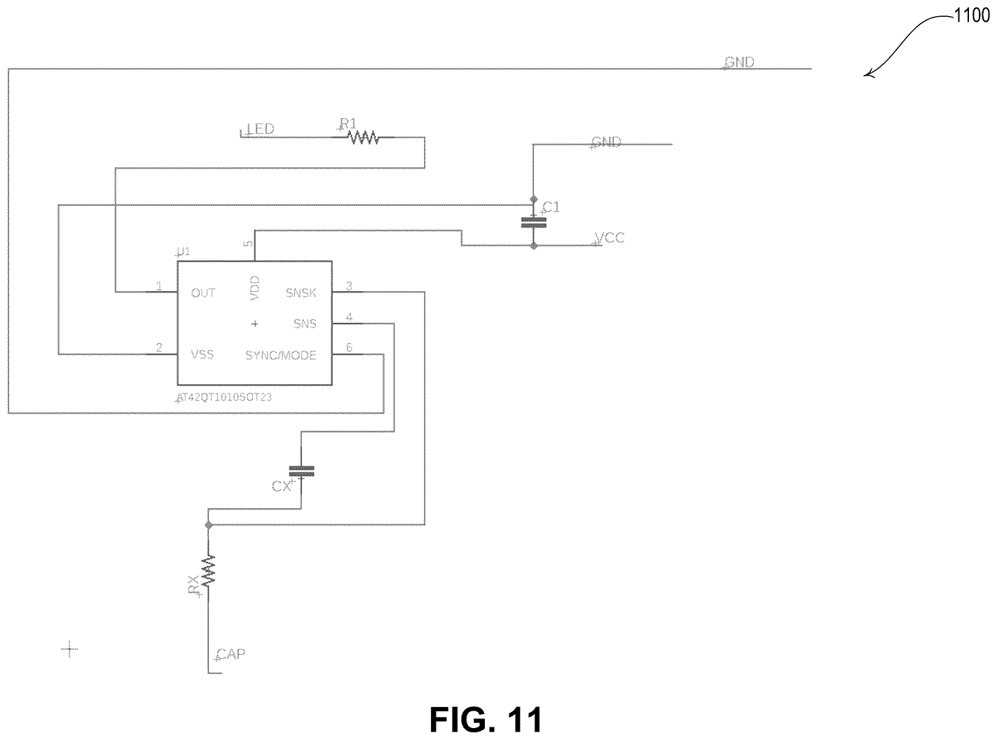

FIG. 10 is a diagram that illustrates an example of a PCB 1000 that may be used in the master control device. The PCB 1000 may be used in conjunction with a capacitive touch circuit (e.g., the capacitive touch circuit 1100 shown in FIG. 11) to turn on the LED when the user touches a touch-responsive area on the master control device. For example, the capacitive touch circuit may be soldered onto the PCB 1000. Using the PCB 1000 may extend the field of capacitance from a relatively small area (e.g., 2.0±0.5 mm\hat{ }2) to a horizontal cross-section of the master control device. For example, the touch-responsive area may have the shape of a ring and may be located on a surface of the handle (e.g., the handle 102) of the master control device. The user may touch any point on the surface of the master control device within the touch-responsive area to activate the PCB 1000.

As shown in FIG. 10, the PCB 1000 may be associated with a first resistance value (e.g., which may be denoted as R1), a second resistance value (e.g., which may be denoted as Rx), and/or a capacitance value (e.g., which may be denoted as Cx). R1 may be approximately 1,000 ohms. Cx and/or Rx may be selected to produce a capacitance sensitivity value that may be appropriate for the wall thickness of the handle of the master control device. The PCB 1000 and/or the capacitive touch circuit 1100 may adjust to the capacitance of an object touching the touch-resistive area and/or may adjust a threshold used to determine when the capacitance changes.

FIG. 11 is a diagram that illustrates an example capacitive touch circuit 1100 that may be used as part of the master control device. The capacitive touch circuit 1100 may be attached (e.g., soldered) to a PCB (e.g., the PCB 1000 shown in FIG. 10). The capacitive touch circuit 1100 may be associated with the first resistance value, the second resistance value, and/or the capacitance value. The capacitive touch circuit 1100 may function using a chip (e.g., an AT42QT1011-TSHR chip). The capacitive touch circuit 1100 may have one or more (e.g., two) inputs and may include a power source and/or a copper coil. The copper coil may be used as a touchpad. The capacitive touch circuit 1100 may have an output, which may be connected to the LED, and may be used when the capacitive touch circuit 1100 is triggered by the user. One or more of the inputs and/or the output may connect to the PCB 1000 using a 0.7 mm via such that wires may be soldered onto the PCB 1000 (e.g., during an assembly process).

FIGS. 12A and 12B illustrate diagrams of an example master control device 1200 in unassembled and assembled states, respectively. As shown in FIG. 12A, the master control device 1200 may include one or more components. For example, the components may be the following: a capacitance coil 1202 (e.g., which may be a copper ring); a PCB 1204 (e.g., the PCB 1000); one or more batteries 1206; a housing 1208 (e.g., an electronics housing); a handle 1210; a first jack 1212 (e.g., a female jack); a second jack 1214 (e.g., a male jack configured to create an electrical connection when inserted into the female jack); a shaft inner tube 1216; a shaft 1218; an LED 1220 (e.g., a surface mounted device (SMD) LED); and/or a tip component 1222. The components may be connected to each other (e.g., during assembly) to create the master control device 1200.

As shown in FIG. 12A, the batteries 1206 may be AAA batteries. A shape and/or size of the housing 1208 and/or the handle 1210 may be selected based on the shape, size, design, and/or the number of the batteries 1206. The LED 1220 may be, for example, a C0402 W pre-soldered micro 0.1 mm copper wired white SMD LED 0402. The first jack 1212 and/or the second jack 1214 may be 3.5 mm jacks and may be, for example, a phone audio connector (e.g., an MJ-164H or KLS2 connector), and may have two contacts. The first jack 1212 and/or the second jack 1214 may be nickel plated and/or may be panel mount jacks. The first jack 1212 may be connected to the second jack 1214 (e.g., when the handle 1210 is attached to the shaft 1218). The connection between the first jack 1212 and the second jack 1214 may allow for an electrical connection between one or more electronic components in the handle 1210 (e.g., the batteries 1206) and one or more electronic components in the shaft 1218 (e.g., the LED 1220 and/or the tip component 1222). The inner components (e.g., the entirety of the inner components) may be attached directly to each other using solder (e.g., without barrel jack adapters).

The shaft 1218 may be printed (e.g., 3D printed) using a transparent PLA filament such that light from the LED 1220 may diffuse through the shaft. A coating of paint may be applied to the shaft 1218 (e.g., during manufacturing and/or assembly of the master control device 1200). Part or all of the shaft 1218 (e.g., the tip of the shaft 1218) may have a thickness of, for example, 2.5±0.5 mm\hat{ }2.

The tip component 1222 may be, for example, an RFID tag and/or a cylindrical magnet. For example, the RFID tag may be used to communicate with a device (e.g., a universal controller) via RFID. The cylindrical magnet may be used communicate with a device via magnetic induction. The master control device 1200 (e.g., or any master control device described herein) may operate in a similar manner when an RFID or magnetic communication is used. A specific tip component may be selected for a master control device based on an intended use of the master control device. For example, if the master control device is intended for consumer use (e.g., inside a venue), the tip component 1222 may be an RFID tag. For example, if the master control device is indented for retail and/or at-home consumer use, the tip component 1222 may be a magnet. Operation with the RFID may be implemented when operating the master control device 1200 near systems that may be affected by the magnet, and vice versa. The shaft inner tube 1216 may be designed (e.g., manufactured) such that it is compatible with multiple tip components. Different tip components may have similar dimensions (e.g., 4 mm×12 mm).

The components included in the master control device 1200 may be assembled as shown in FIG. 12B. For example, the capacitance coil 1202, the PCB 1204, and/or the batteries 1206 may be placed in the housing 1208. The housing 1208 and/or the first jack 1212 may be placed in the handle 1210 (e.g., during manufacture of the master control device 1200). The first jack 1212 may be connected or attached to the housing 1208 such that the first jack 1212 is electrically connected to the components in the housing 1208. The LED 1220 and/or the tip component 1222 may be placed in the shaft inner tube 1216. The shaft inner tube and/or the second jack 1214 may be placed in the shaft 1218 (e.g., during manufacture of the master control device 1200). The second jack 1214 may be connected or attached to the shaft inner tube 1216 such that the second jack 1214 is electrically connected to the components in the shaft inner tube 1216. As shown in FIG. 12B, the shaft inner tube 1216 and the handle 1210 may be attached to each other by means of a screw thread mechanism.

Upon attachment of the shaft inner tube 1216 and the handle 1210, the first jack 1212 and the second jack 1214 may be connected to each other to form an electrical connection is formed between the components in the housing 1208 and the components in the shaft inner tube 1216. For example, the first jack 1212 and the second jack 1214 may be connected to each other such that the LED 1220 turns on when a user of the master control device 1200 touches a touch-responsive area created by the capacitance coil 1202 and/or the PCB 1204. For example, it may be determined that the user is touching the touch-responsive area when the capacitance in the touch-responsive area is above a threshold value and/or when a predefined portion of the touch-responsive area is covered by the user's hand. This connection may be established directly with solder and without a jack.

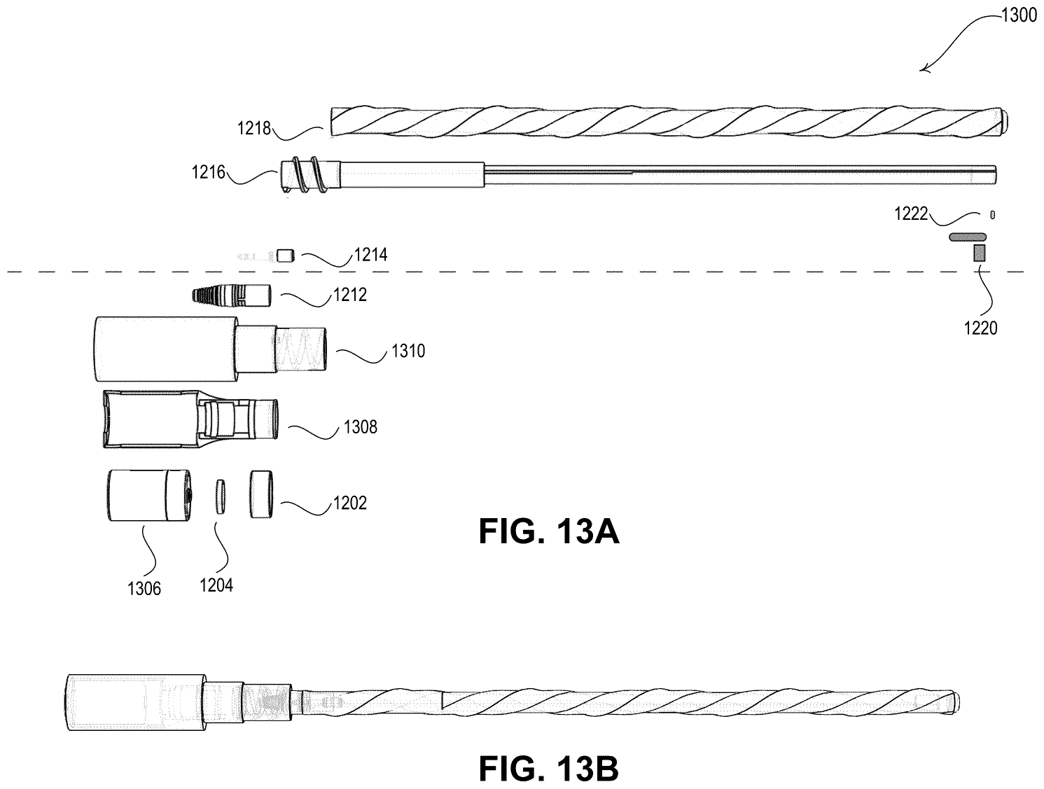

FIGS. 13A and 13B illustrate diagrams of an example master control device 1300 in unassembled and assembled states, respectively. As shown in FIG. 13A, the master control device 1300 may include one or more components. For example, the components may be the following: the capacitance coil 1202; the PCB 1204; a battery 1306; a housing 1308 (e.g., an electronics housing); a handle 1310; the first jack 1212; the second jack 1214; the shaft inner tube 1216; the shaft 1218; the LED 1220; and/or the RFID tag/cylindrical magnet 1222. The components may be connected to each other (e.g., during assembly) to create the master control device 1300. As shown in FIG. 13A, the battery 1306 may be a CR2 battery (e.g., an ultra-lithium CR2 2PK battery). A shape and/or size of the housing 1308 and/or the handle 1310 may be selected based on the shape, size, design, and/or the number of the batteries 1306.

The components included in the master control device 1300 may be assembled as shown in FIG. 13B. For example, the capacitance coil 1202, the PCB 1204, and/or the battery 1306 may be placed in the housing 1308. The housing 1308 and/or the first jack 1212 may be placed in the handle 1310 (e.g., during manufacture of the master control device 1300). The first jack 1212 may be connected or attached to the housing 1308 such that the first jack 1212 is electrically connected to the components in the housing 1308. The LED 1220 and/or the tip component 1222 may be placed in the shaft inner tube 1216. The shaft inner tube and/or the second jack 1214 may be placed in the shaft 1218 (e.g., during manufacture of the master control device 1300). The second jack 1214 may be connected or attached to the shaft inner tube 1216 such that the second jack 1214 is electrically connected to the components in the shaft inner tube 1216. As shown in FIG. 13B, the shaft inner tube 1216 and the handle 1310 may be attached to each other by means of a screw thread mechanism.

Upon attachment of the shaft inner tube 1216 and the handle 1310, the first jack 1212 and the second jack 1214 may be connected to each other such that an electrical connection is formed between the components in the housing 1308 and the components in the shaft inner tube 1216. For example, the first jack 1212 and the second jack 1214 may be connected to each other such that the LED 1220 turns on when a user of the master control device 1300 touches a touch-responsive area created by the capacitance coil 1202 and/or the PCB 1204. For example, it may be determined that the user is touching the touch-responsive area when the capacitance in the touch-responsive area is above a threshold value and/or when a predefined portion of the touch-responsive area is covered by the user's hand.

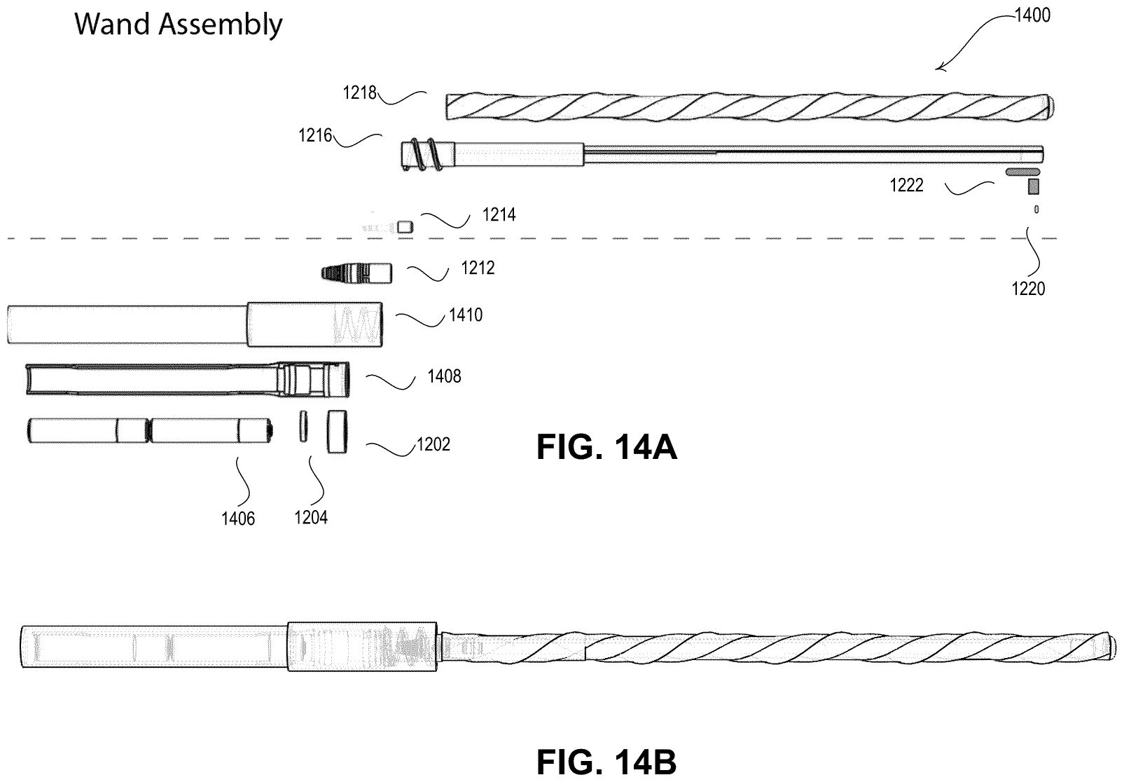

FIGS. 14A and 14B illustrate diagrams of an example master control device 1400 in unassembled and assembled states, respectively. As shown in FIG. 14A, the master control device 1400 may include one or more components. For example, the components may be the following: the capacitance coil 1202; the PCB 1204; one or more batteries 1406; a housing 1408 (e.g., an electronics housing); a handle 1410; the first jack 1212; the second jack 1214; the shaft inner tube 1216; the shaft 1218; the LED 1220; and/or the RFID tag/cylindrical magnet 1222. The components may be connected to each other (e.g., during assembly) to create the master control device 1400. As shown in FIG. 14A, the batteries 1406 may be AAAA batteries. A shape and/or size of the housing 1408 and/or the handle 1410 may be selected based on the shape, size, design, and/or the number of the batteries 1406.

The components included in the master control device 1400 may be assembled as shown in FIG. 14B. For example, the capacitance coil 1202, the PCB 1204, and/or the batteries 1406 may be placed in the housing 1408. The housing 1408 and/or the first jack 1212 may be placed in the handle 1410 (e.g., during manufacture of the master control device 1400). The first jack 1212 may be connected or attached to the housing 1408 such that the first jack 1212 is electrically connected to the components in the housing 1408. The LED 1220 and/or the tip component 1222 may be placed in the shaft inner tube 1216. The shaft inner tube and/or the second jack 1214 may be placed in the shaft 1218 (e.g., during manufacture of the master control device 1400). The second jack 1214 may be connected or attached to the shaft inner tube 1216 such that the second jack 1214 is electrically connected to the components in the shaft inner tube 1216. As shown in FIG. 14B, the shaft inner tube 1216 and the handle 1410 may be attached to each other by means of a screw thread mechanism.

Upon attachment of the shaft inner tube 1216 and the handle 1410, the first jack 1212 and the second jack 1214 may be connected to each other such that an electrical connection is formed between the components in the housing 1408 and the components in the shaft inner tube 1216. For example, the first jack 1212 and the second jack 1214 may be connected to each other such that the LED 1220 turns on when a user of the master control device 1400 touches a touch-responsive area created by the capacitance coil 1202 and/or the PCB 1204. For example, it may be determined that the user is touching the touch-responsive area when the capacitance in the touch-responsive area is above a threshold value and/or when a predefined portion of the touch-responsive area is covered by the user's hand.

The assembled master control devices 1200, 1300, 1400 shown in FIGS. 12B, 13B, and 14B respectively, may differ in the type of battery used to power the master control device. For example, the master control device 1200 may use one or more AAA batteries, the master control device 1300 may use one or more CR2 batteries (e.g., ultra-lithium CR2 2PK batteries), and/or the master control device 1400 may use one or more AAAA batteries. A type of battery may be selected for a master control device based on a desired handle design (e.g., due to the variation in battery geometry).

In an embodiment, a master control device (e.g., the master control device 1200, 1300, and/or 1400) may include a port that may be used to charge the battery in the master control device. For example, the master control device may connect to a wall outlet via a wired connection. The port may be located in a handle of the master control device (e.g., the handle 1208, 1308, and/or 1408). Alternatively, the batteries may be charged via wireless magnetic induction.

As shown in FIGS. 12B, 13B, and 14B, the shaft 1218 may be secured (e.g., attached and/or connected) to one of the handles 1210, 1310, or 1410. The handles 1210, 1310, 1410 and/or the shaft 1218 may be interchangeable. For example, the shaft 1218 may be (e.g., initially) secured to the handle 1210 to generate the master control device 1200. The handle 1210 may be replaced by detaching the handle 1210 from the shaft 1218, and securing the handle 1310 to the shaft 1218 to generate the master control device 1300. The shaft 1218 may be secured to a handle using a screw thread mechanism. An audio jack (e.g., which may include the first jack 1212 and/or the second jack 1214) may be used to generate a dual pole electrical connection.

Using the audio jack may allow for rotational motion while maintaining electrical contact. The two poles of the electrical connection may be located at the center of rotation relative to the shaft 1218 and the handle, which may allow for the connection to be maintained despite the angular position of the two poles relative to each other.

FIG. 15 illustrates a diagram of example RFID and LED mounting geometries in the master control device. For example, FIG. 15 may illustrate RFID and/or LED mounting geometries (e.g., dimensions) in the shaft inner tube 1216 and/or the shaft 1218. The dimensions may be selected to generate an optimum light diffusion while maintaining an appropriate range for registering the RFID tag 1222.

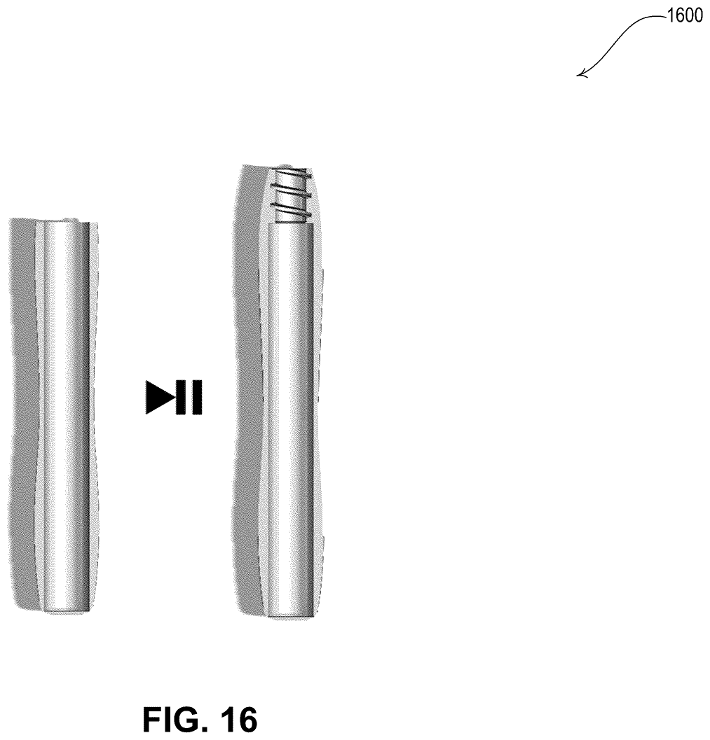

FIG. 16 is a diagram that illustrates an example manufacturing of the master control device. One or more components of the master control devices 1200, 1300, 1400 may be created via 3D printing (e.g., fused deposition modeling (FDM) printing). For example, 3D printing may be used to generate a handle (e.g., the handle 1210, 1310, and/or 1410) and/or a housing (e.g., the housing 1208, 1308, and/or 1408). As shown in FIG. 16, a portion of the handle 1210 may be (e.g., initially) printed such that a cavity is present. After the portion of the handle 1210 is complete, printing may be (e.g., automatically) paused, and one or more electronic components (e.g., the capacitance coil 1202, the PCB 1204, and/or one or more batteries) may be inserted into the cavity and connected to the printed portion of the handle 1210. The electronic components may be attached to (e.g., inside of) the housing 1208 upon insertion to the cavity. The remaining portion of the handle 1210 may be printed (e.g., such that the electronic components are embedded within the housing 1208 and/or the handle 1210).

3D printing may be used to generate the shaft 1218 and/or the shaft inner tube 1216 (e.g., in a similar manner as for the housing 1208 and/or the handle 1210). For example, a portion of the shaft 1218 may be (e.g., initially) printed such that a cavity (e.g., a notch) is present. After the portion of the shaft 1218 is complete, printing may be (e.g., automatically) paused, and one or more electronic components (e.g., the LED 1220 and/or the tip component 1222) may be inserted into the cavity and connected to the printed portion of the shaft 1218. The electronic components may be attached to (e.g., inside of) the shaft inner tube 1216 upon insertion to the cavity. The remaining portion of the shaft 1218 may be printed (e.g., such that the electronic components are embedded within the shaft inner tube 1216 and/or the shaft 1218).

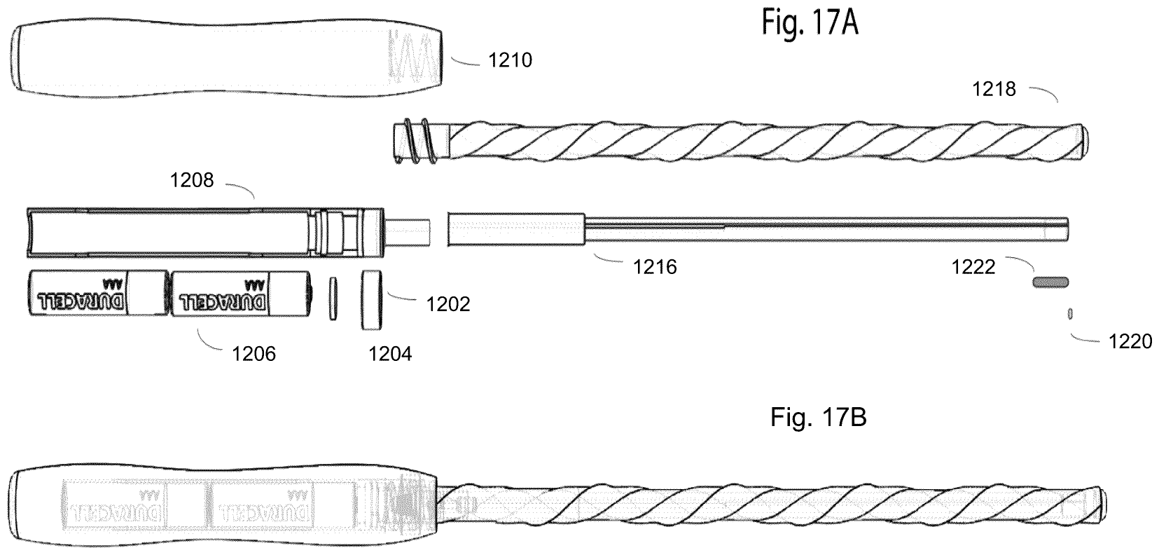

FIGS. 17A and 17B illustrate diagrams of an example master control device 1200 in unassembled and assembled states, respectively. As shown in FIG. 17A, the master control device 1200 may include one or more components. For example, the components may include one or more of the following: a capacitance coil 1202 (e.g., which may be a copper ring); a PCB 1204 (e.g., the PCB 1000); one or more batteries 1206; a housing 1208 (e.g., an electronics housing); a handle 1210; a shaft inner tube 1216; a shaft 1218; an LED 1220 (e.g., a surface mounted device (SMD) LED); and/or a tip component 1222 that may be a cylindrical magnet or a RFID tag. The components may be connected to each other (e.g., during assembly) to create the master control device 1200.

As shown in FIG. 17A, the batteries 1206 may be AAA batteries. A shape and/or size of the housing 1208 and/or the handle 1210 may be selected based on the shape, size, design, and/or the number of the batteries 1206. The LED 1220 may be, for example, a C0402 W pre-soldered micro 0.1 mm copper wired white SMD LED 0402. The soldered connection between the housing 1208 and the shaft inner tube 1216 may allow for an electrical connection between one or more electronic components in the handle 1210 (e.g., the batteries 1206) and one or more electronic components in the shaft 1218 (e.g., the LED 1220 and/or the tip component 1222).

Although features and elements are described herein in particular combinations, each feature or element can be used alone or in any combination with the other features and elements. The methods described herein may be implemented in a computer program, software, or firmware incorporated in a computer-readable medium for execution by a computer or processor. Examples of computer-readable media include electronic signals (transmitted over wired or wireless connections) and computer-readable storage media. Examples of computer-readable storage media include, but are not limited to, a read only memory (ROM), a random access memory (RAM), removable disks, and optical media such as CD-ROM disks, and digital versatile disks (DVDs).

What is claimed is:

1. A system comprising:
a master control device comprising:
a handle comprising a proximal section and a distal section, wherein the distal section of the handle comprises a cavity;
a housing configured to be placed within the cavity of the handle, the housing comprising:
a first battery;
a printed circuit board (PCB); and
a capacitive touch coil configured to generate, in conjunction with the PCB,
a touch-responsive area on an outer surface of the handle; and
a shaft comprising a proximal section and a distal section, wherein the shaft further comprises:
an inner tube comprising a proximal section and a distal section; and
a tip component comprising a magnet;
wherein the handle and the shaft are configured to be attached together to generate the master control device such that the master control device has a length within a range of 250 mm to 350 mm;
a universal transmitter comprising:
a Hall effect sensor configured to determine whether the tip component is within a pre-defined range of the Hall effect sensor;
an LED; and
a transmitter configured to transmit, via RF signals, an indication that indicates that the tip component is within the pre-defined range of the Hall effect sensor; and
a smart socket comprising:
a receiver configured to receive, via the RF signals, the indication that indicates that the tip component is within the pre-defined range of the Hall effect sensor;
a mains socket configured to receive a connector of a controllable device and to provide power to the controllable device; and
a control circuit configured to send a command to the controllable device to perform an action based on receiving the indication that indicates that the tip component is within the pre-defined range of the Hall effect sensor.

2. The system of claim 1, wherein the length of the master control device is within a range of 270 mm to 330 mm.

3. The system of claim 1, wherein the length of the master control device is within a range of 290 mm to 310 mm.

4. The system of claim 1, wherein the handle and the shaft are configured to be detachable from each other.

5. The system of claim 1, wherein the housing comprises glass.

6. The system of claim 1, wherein the LED is configured to provide feedback to a user of the master control device.

7. The system of claim 6, wherein the LED is configured to provide feedback to the user of the master control device by turning on when the tip component enters within the pre-defined range of the Hall effect sensor and turning off when the tip component leaves the pre-defined range of the Hall effect sensor.

8. The system of claim 1, wherein the capacitive touch coil comprises a power source and a copper coil.

9. The system of claim 1, wherein the LED is a surface-mounted device (SMD) LED.

10. The system of claim 1, wherein the handle and the shaft of the master control device are configured to be attached together via a screw thread.

11. The system of claim 1, wherein the touch-responsive area has the shape of a ring.

12. The system of claim 1, wherein the control circuit being configured to send a command to the controllable device to perform an action comprises the control circuit being configured to send a command to the controllable device to enter a first state.

13. The system of claim 12, wherein the first state is an on state.

14. The system of claim 1, wherein the controllable device comprises a lamp, and wherein the control circuit being configured to send a command to the controllable device to perform an action comprises the control circuit being configured to send a command to the lamp to turn on or off.

15. The system of claim 1, wherein the universal transmitter further comprises a second battery.

16. The system of claim 1, wherein the RF signals comprise WiFi signals.

17. The system of claim 1, wherein the controllable device comprises a smart home device.

18. The system of claim 17, wherein the control circuit being configured to send a command to the controllable device to perform an action comprises the control circuit being configured to send a command to the smart home device to enter an active state.

19. A system comprising:
a master control device comprising:
a handle comprising a proximal section and a distal section, wherein the distal section of the handle comprises a cavity;
a housing configured to be placed within the cavity of the handle, the housing comprising:
a first battery;
a printed circuit board (PCB); and
a capacitive touch coil configured to generate, in conjunction with the PCB,
a touch-responsive area on an outer surface of the handle; and
a shaft comprising a proximal section and a distal section, wherein the shaft further comprises:
an inner tube comprising a proximal section and a distal section; and
a tip component comprising a magnet;
wherein the handle and the shaft are configured to be attached together to generate the master control device such that the master control device has a length within a range of 250 mm to 350 mm;
a universal transmitter comprising:
a Hall effect sensor configured to determine whether the tip component is within a pre-defined range of the Hall effect sensor;
an LED; and
a transmitter configured to transmit, via RF signals, an indication that indicates that the tip component is within the pre-defined range of the Hall effect sensor; and
a smart device comprising:
a receiver configured to receive, via the RF signals, the indication that indicates that the tip component is within the pre-defined range of the Hall effect sensor;
a microphone configured to listen for a spoken word or phrase associated with the universal transmitter; and
a control circuit configured to send, to a controllable device, a command to perform an action based on receiving the indication that indicates that the tip component is within the pre-defined range of the Hall effect sensor and the spoken word or phrase associated with the universal transmitter.

20. The system of claim 19, wherein the control circuit of the smart device is further configured to:
receive an indication of the spoken word or phrase associated with the universal transmitter from the microphone;
access a database comprising one or more associations between spoken words or phrases and one or more respective actions; and
determine the command to perform the action based on the one or more associations comprised in the database.
